(19) United States
(12) Patent Application Publication
(10) Pub. No.: US 2025/0143027 A1
(43) Pub. Date: May 1, 2025

(54) DISPLAY DEVICE AND METHOD FOR FABRICATING THE SAME

(71) Applicant: Samsung Display Co., LTD., Yongin-si (KR)

(72) Inventors: Kyung Rock SON, Yongin-si (KR); Sun PARK, Yongin-si (KR); Hui Won YANG, Yongin-si (KR); Jae Bok YOO, Yongin-si (KR); Jae Phil LEE, Yongin-si (KR)

(21) Appl. No.: 18/676,017

(22) Filed: May 28, 2024

(30) Foreign Application Priority Data
Nov. 1, 2023 (KR) 10-2023-0148869

(51) Int. Cl. H01L 33/38; H01L 25/16; H01L 33/40

(52) U.S. Cl. CPC H10H 20/8314; H01L 25/167; H10H 20/835; H10H 20/032

(57) ABSTRACT

A display device includes a substrate, first and second electrodes above the substrate, an organic pattern layer between the first and second electrodes, a light-emitting element above the organic pattern layer, first and second contact electrodes above the light-emitting element, a first reflective electrode on the first electrode and a second reflective electrode on the second electrode extending along a side of the light-emitting element, a via layer covering a portion of the first and second reflective electrodes, and defining first and second connection holes, a first connection electrode above the via layer, connecting the first reflective and contact electrodes through the first connection hole, and contacting the first reflective electrode on a side of the light-emitting element, and a second connection electrode connecting the second reflective and contact electrodes through the second connection hole, and contacting the second reflective electrode on a side of the light-emitting element.

### CROSS-REFERENCE TO RELATED APPLICATION

This application claims priority to, and the benefit of, Korean Patent Application No. 10-2023-0148869 filed on Nov. 1, 2023, in the Korean Intellectual Property Office, the contents of which in its entirety are herein incorporated by reference.

### BACKGROUND

### 1. Field

The present disclosure relates to a display device, and to a method of manufacturing the same.

### 2. Description of the Related Art

With the development of the information society, the demand for display devices for displaying images is increasing in various forms. The display device may be a flat panel display, such as a liquid crystal display, a field emission display, a light-emitting display, and the like. The light-emitting display device may include an organic light-emitting display device including an organic light-emitting diode element as a light-emitting element, and a miniature light-emitting display device including a micro light-emitting diode element (hereinafter referred to as a micro light-emitting element) as a light-emitting element.

When manufacturing a micro light-emitting display device, defective bonding between the light-emitting element and the electrode may occur due to outgassing generated during the processing of the organic layer surrounding the micro light-emitting element. As a result of this bonding failure, the micro emitting element may not emit light.

Aspects of embodiments of the present disclosure provide a display device and a method of manufacturing the same that may reduce or prevent a micro emitting element from being electrically connected to a pixel electrode or a common electrode.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes a substrate, a first electrode and a second electrode above the substrate and spaced apart from each other, an organic pattern layer between the first electrode and the second electrode, a light-emitting element above the organic pattern layer, a first contact electrode and a second contact electrode above a top surface of the light-emitting element, a first reflective electrode on the first electrode, and extending along a side of the light-emitting element, a second reflective electrode on the second electrode, and extending along a side of the light-emitting element, a via layer covering a portion of the first reflective electrode and the second reflective electrode, and defining a first connection hole and a second connection hole, a first connection electrode above the via layer, connecting the first reflective electrode and the first contact electrode through the first connection hole, and contacting the first reflective electrode on a side of the light-emitting element, and a second connection electrode connecting the second reflective electrode to the second contact electrode through the second connection hole, and contacting the second reflective electrode on a side of the light-emitting element.

The first connection hole may overlap the first electrode, and may expose the first reflective electrode, wherein the second connection hole overlaps the second electrode, and exposes the second reflective electrode.

The first reflective electrode and the first connection electrode may be connected in parallel with the via layer interposed therebetween, wherein the second reflective electrode and the second connection electrode are connected in parallel with the via layer interposed therebetween.

The light-emitting element may include a third semiconductor layer above the organic pattern layer, a second semiconductor layer above the third semiconductor layer, an active layer above the second semiconductor layer, a first semiconductor layer above the active layer, and a protective film on a side surface of the third semiconductor layer, a side surface of the second semiconductor layer, a side surface of the active layer, and a side surface and a top surface of the first semiconductor layer, and defining a second opening and a third opening, wherein the first contact electrode is in the second opening, and is connected to the first semiconductor layer, and wherein the second contact electrode is in the third opening, and is connected to the second semiconductor layer.

The via layer may be lower than the active layer.

The first reflective electrode and the second reflective electrode may be higher than the active layer, wherein one end of the first reflective electrode and the second reflective electrode protrudes from the top surface of the via layer.

The first reflective electrode and the second reflective electrode may have a higher reflectivity than the first connection electrode and the second connection electrode.

The first electrode, the second electrode, the first reflective electrode, and the second reflective electrode may include an opaque metal material, wherein the first connection electrode and the second connection electrode include a transparent conductive oxide.

The first electrode and the second electrode may be spaced apart from each other on a same plane, and may protrude outwardly from the light-emitting element.

A width of the organic pattern layer may be wider than a width of the light-emitting element.

The display device may further include a reflective layer on a lower surface of the organic pattern layer between the first electrode and the second electrode, wherein the reflective layer has a higher reflectivity than the first connection electrode and the second connection electrode.

The display device may further include a partition wall above the via layer, defining a light-emitting area, and filling connection holes defined by the via layer, and a wavelength conversion layer in the space defined by the partition wall.

The display device may further include a capping layer, an overcoat layer, and a color filter layer sequentially above the wavelength conversion layer and the partition wall.

According to one or more embodiments, a method of manufacturing display device includes providing a light-emitting element above a light-emitting element substrate, forming a first electrode and a second electrode spaced apart from each other above a substrate, forming an organic pattern layer between the first electrode and the second electrode, fixing the light-emitting element of the light-emitting element substrate to the organic pattern layer, forming a first reflective electrode on a side of the light-emitting element on the first electrode, forming a second reflective electrode extending on the side of the light-emitting element on the second electrode, forming a via layer defining a first connection hole that overlaps the first electrode, and that exposes the first reflective electrode, and also defining a second connection hole that overlaps the second electrode, and that exposes the second reflective electrode, forming a first connection electrode above the via layer and contacting the first reflective electrode on the side of the light-emitting element for connecting the first reflective electrode and a first contact electrode through the first connection hole, forming a second connection electrode connecting the second reflective electrode to a second contact electrode through the second connection hole, and contacting the second reflective electrode on the side of the light-emitting element.

Forming the via layer may include forming a via layer to cover a portion of the first reflective electrode and the second reflective electrode and to be lower than an active layer of the light-emitting element, etching the first connection hole exposing the first reflective electrode at a position overlapping with the first electrode, and etching the second connection hole exposing the second reflective electrode at a position overlapping with the second electrode.

The first reflective electrode and the second reflective electrode may be higher than the active layer in forming the second reflective electrode.

The first reflective electrode and the second reflective electrode may have a higher reflectivity than the first connection electrode and the second connection electrode.

Forming the first electrode and the second electrode spaced apart from each other on the substrate may further include forming a recess on the light-emitting element substrate, forming the first electrode and the second electrode with the recess therebetween, and forming a reflective layer in the recess.

Fixing the light-emitting element to the organic pattern layer may further include curing the organic pattern layer at a first temperature, inserting a portion of the light-emitting element into the organic pattern layer, and curing the organic pattern layer at a second temperature higher than the first temperature.

The method may further include forming a partition wall above a via layer fixed to the organic pattern layer and defining a light-emitting area, forming a first wavelength conversion layer in a region corresponding to a first sub-pixel, forming a second wavelength conversion layer in a region corresponding to a second sub-pixel, an forming a light transmission layer in a region corresponding to a third sub-pixel among the regions compartmentalized by the partition wall, and forming a first color filter on the first wavelength conversion layer, forming a second color filter on the second wavelength conversion layer, and forming a third color filter on the light transmission layer.

The display device according to one or more embodiments may reduce or minimize the possibility of a disconnection between the light-emitting element and the circuit electrode, thereby reducing or minimizing a defect in the dark spot of a pixel. Furthermore, it is possible to reduce or minimize mixing between pixels.

However, the aspects of the present disclosure are not limited to the aforementioned aspects, and various other aspects are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is a circuit diagram illustrating a first sub-pixel of a display panel according to one or more embodiments.

FIG. 5 is a circuit diagram illustrating a first sub-pixel of a display panel, according to one or more other embodiments.

FIG. 6 is a layout diagram illustrating pixels of a display area according to one or more embodiments.

FIG. 7 is a cross-sectional view illustrating a cross-section of the display panel taken along the lines I1-I1′, I2-I2′, and I3-I3′ of FIG. 6, in one or more embodiments.

FIG. 8A is a cross-sectional view illustrating one example of area A in FIG. 7 in detail, FIG. 8B is a cross-sectional view illustrating another example of area A in FIG. 7 in detail, FIG. 8C is a cross-sectional view illustrating another example of area A in FIG. 7 in detail, and FIG. 8D is a cross-sectional view illustrating another example of area A of FIG. 7 in detail.

FIG. 9 is an enlarged view of the light-emitting element described with reference to FIG. 8A.

FIG. 10 is a diagram to illustrate a contact path between a first electrode and a first contact electrode in the display panel illustrated with reference to FIG. 8A.

FIG. 11 is a cross-sectional view illustrating another example of area A of FIG. 7 in detail.

FIG. 12 is a cross-sectional view illustrating another example of a cross-section of the display panel taken along the lines I1-I1′, I2-I2′, and I3-I3′ of FIG. 6.

FIG. 13 is a cross-sectional view illustrating area B of FIG. 12 in detail, according to one or more embodiments.

FIG. 14 is a cross-sectional view illustrating another example of area B in FIG. 12 in detail.

FIG. 15 is a flowchart illustrating a method of manufacturing a display device according to one or more embodiments.

FIGS. 16 to 27 are cross-sectional views to illustrate a method of manufacturing a display device according to one or more embodiments.

FIG. 28 is a flowchart illustrating operation S110 of FIG. 15 in detail.

FIGS. 29 to 35 are cross-sectional views to illustrate operation S110.

FIG. 36 is a diagram schematically showing a virtual reality device including a display device according to one or more embodiments;

FIG. 37 is a diagram schematically showing a smart device including a display device according to one or more embodiments;

FIG. 38 is a diagram schematically showing a vehicle including a display device according to one or more embodiments; and

FIG. 39 is a diagram schematically showing a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

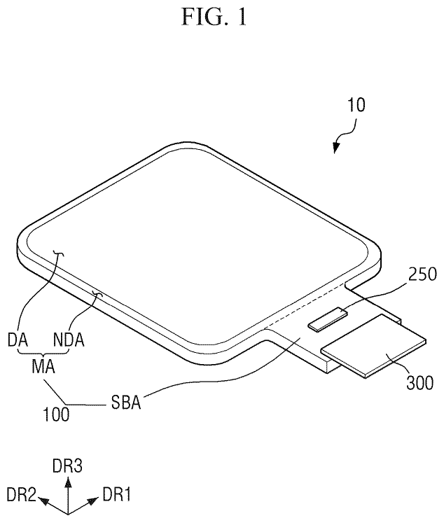

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IOT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light-emitting display device, but the present disclosure is not limited thereto. On the other hand, a micro light-emitting diode referred to as a light-emitting element in the following for convenience of explanation.

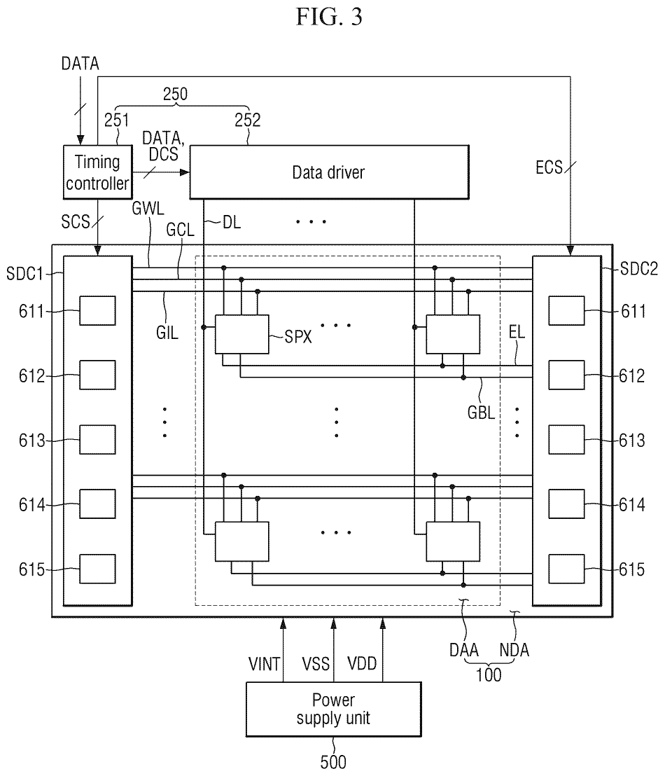

The display device 10 includes a display panel 100, a display driver 250, a circuit board 300, and a power supply circuit 500 (see FIG. 3).

The display panel 100 may be formed as a rectangular-shaped plane having a short side in the first direction DR1, and a long side in the second direction DR2 that crosses the first direction DR1. A corner where the short side in the first direction DR1 and the long side in the second direction DR2 meet may be rounded to have a curvature (e.g., predetermined curvature), or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends, and may include curved portions with a constant curvature or a changing curvature. Additionally, the display panel 100 may be formed to be flexible, such as to be able to be bent, curved, bent, folded, or rolled.

The substrate SUB of the display panel 100 may include a main area MA and a sub-area SBA.

The main area MA may include a display area DA that displays an image, and a non-display area NDA that is a peripheral area of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be located on the bottom surface of the display panel 100. When the sub-area SBA is bent, it may overlap the main area MA in the third direction DR3, which is the thickness direction of the display panel 100. The display driver 250 may be located in the sub-area SBA.

The display driver 250 may generate signals and voltages for driving the display panel 100. The display driver 250 may be formed as an integrated circuit (IC) and attached to the indication panel 100 using a chip-on-glass (COG) method, a chip-on-plastic (COP) method, or an ultrasonic bonding method but is not limited thereto. For example, the display driver 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display driver 250. The display panel 100 and the display driver 250 may receive digital video data, timing signals, and driving voltages through the circuit board 300. The circuit board 300 may be a flexible film, such as a flexible printed circuit board, a printed circuit board, or a chip on film.

The power supply circuit 500 may generate a plurality of panel driving voltages according to an external power supply voltage. The power supply circuit 500 may be formed as an integrated circuit (IC) and attached to the circuit board 300 using a COF method.

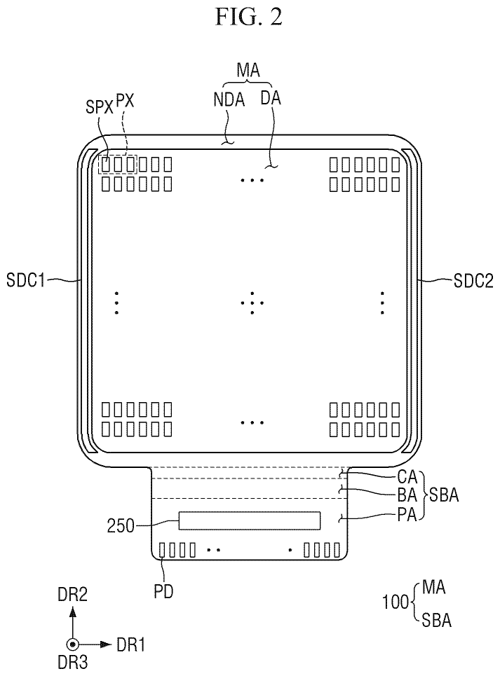

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be generally placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to surround the display area DA. The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, it is not limited to. Each of the first scan driver SDC1 and the second scan driver SDC2 may be electrically connected to the display driver 250 through scan fan-out lines. Each of the first scan driver SDC1 and the second scan driver SDC2 may receive a scan control signal from the display driver 250, may generate scan signals according to the scan control signal, and may output them to the scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub-area SBA is less than the length of the first direction DR1 of the main area MA, or may be substantially equal to the length of the first direction DR1 of the main area MA. The sub-area SBA may be curved, and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driver 250 are located. The display driver 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is a bent area. When the bending area BA is bent, the pad area PA may be located below the connection area CA and below the main area MA. The bending area BA may be located between the connection area CA and the pad area PA. One side of the bending area BA may be in contact with the connection area CA, and the other side of the bending area BA may be in contact with the pad area PA.

FIG. 3 is a block diagram illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and in the second direction DR2. The plurality of scan lines and the plurality of emission control lines EL may extend in the first direction DR1, and may be arranged in the second direction DR2. The plurality of data lines DL may extend in the second direction DR2, and may be arranged in the first direction DR1. The plurality of scan lines may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL, and may emit light-emitting elements according to the data voltage.

The non-display area NDA includes a first scan driver SDC1, a second scan driver SDC2, and a display driver 250.

Each of the first scan driver SDC1 and the second scan driver SDC2 may include a write scan signal output 611, a control scan signal output 612, an initialization scan signal output 613, a bias scan signal output 614, and a light-emitting signal output 615. Each of the write scan signal output 611, the control scan signal output 612, the initialization scan signal output 613, the bias scan signal output 614, and the light-emitting signal output 615 may receive a scan timing control signal SCS from the timing control circuit 400. The write scan signal output 611 may generate write scan signals according to the scan timing control signal SCS of the timing control circuit 400 and may sequentially output them to the write scan lines GWL. The control scan signal output 612 may generate control scan signals according to the scan timing control signal SCS, and may sequentially output them to the control scan lines GCL. The initialization scan signal output 613 may generate initialization scan signals according to the scan timing control signal SCS, and may sequentially output them to the initialization scan lines GIL. The bias scan signal output 614 may generate bias scan signals according to the scan timing control signal SCS, and may sequentially output them to the bias scan lines EBL. The light-emitting signal output 615 may generate light-emitting control signals according to the scan timing control signal SCS, and may sequentially output them to the emission control lines EL.

The display driver 250 includes a timing control circuit 251 and a data driver 252.

The data driver 252 may receive digital video data DATA and a data timing control signal DCS from the timing control circuit 251. The data driver 252 converts digital video data DATA into analog data voltages according to the data timing control signal DCS, and outputs them to the data lines DL. In this case, the sub-pixels SPX are selected by the write scan signals of the first scan driver SDC1 and the second scan driver SDC2, and data voltages may be supplied to the selected sub-pixels SPX.

The timing control circuit 251 may receive digital video data and timing signals from an external source. The timing control circuit 251 may generate the scan timing control signal SCS and the data timing control signal DCS to control the display panel 100 according to timing signals. The timing control circuit 400 may output the scan timing control signal SCS to the first scan driver SDC1 and the second scan driver SDC2. The timing control circuit 251 may output digital video data DATA and a data timing control signal DCS to the data driver 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT to the display panel 100.

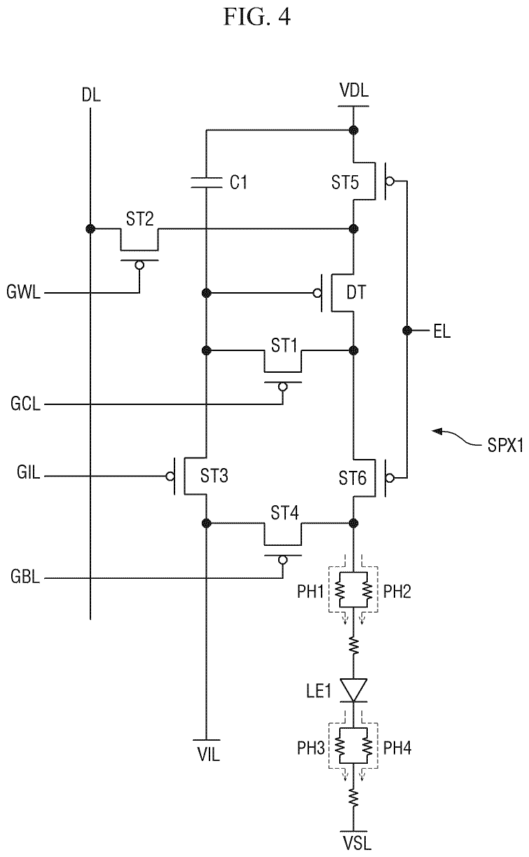

FIG. 4 is a circuit diagram illustrating a first sub-pixel of a display panel according to one or more embodiments.

Referring to FIG. 4, the first sub-pixel SPX1 according to one or more embodiments may be connected to scan lines GWL, GIL, GCL, and GBL, an emission line EL, and a data line DL. For example, the first sub-pixel SPX1 may be connected to the write scan line GWL, the initialization scan line GIL, the control scan line GCL, the bias scan line GBL, the emission line EL, and the data line DL.

The first sub-pixel SPX1 according to one or more embodiments includes a driving transistor DT, switch elements, a capacitor C1, and a first light-emitting element LE1. The switch elements include first to sixth transistors ST1, ST2, ST3, ST4, ST5, and ST6.

The driving transistor DT includes a gate electrode, a first electrode, and a second electrode. The driving transistor DT controls the drain-source current (hereinafter referred to as “driving current”) flowing between the first electrode and the second electrode according to the data voltage applied to the gate electrode.

The first light-emitting element LE1 may be a micro light-emitting diode.

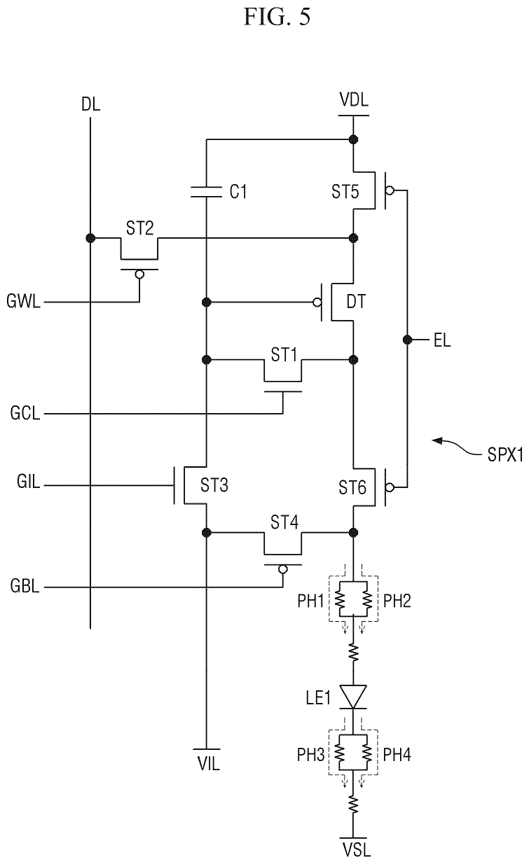

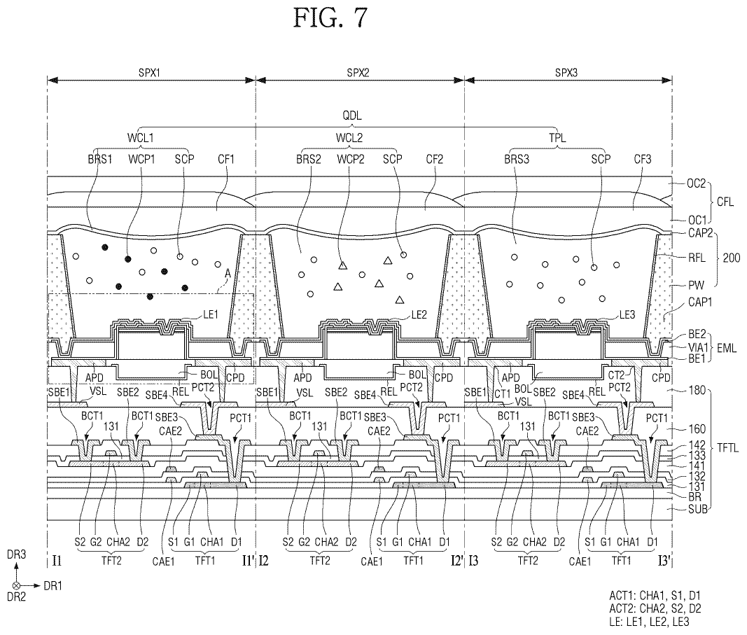

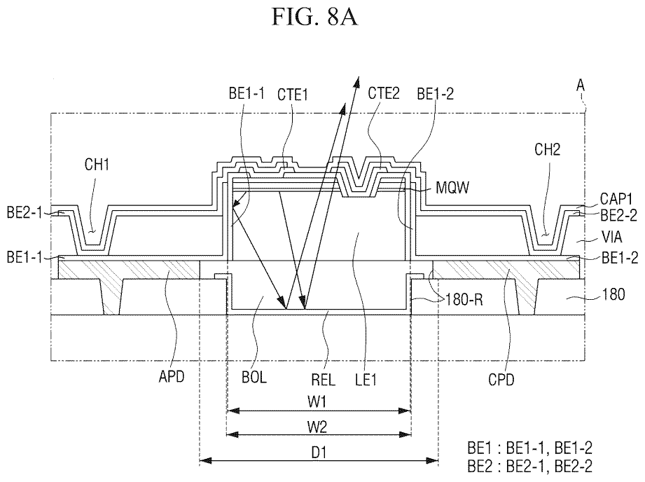

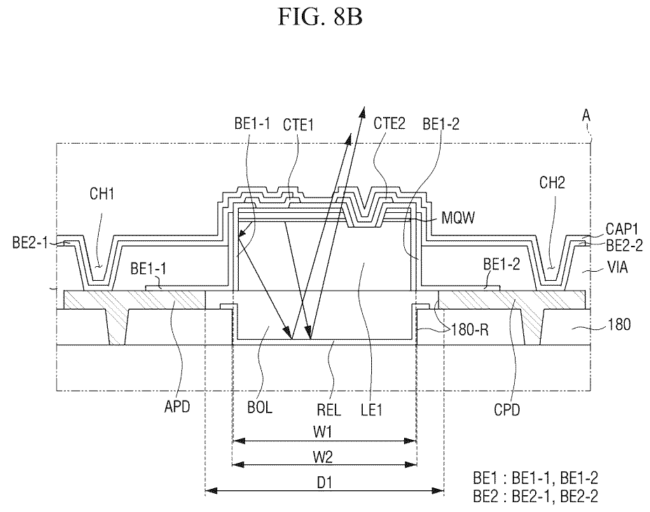

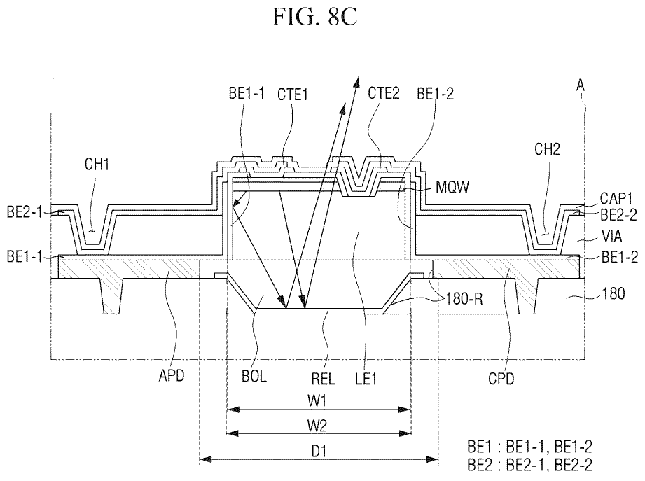

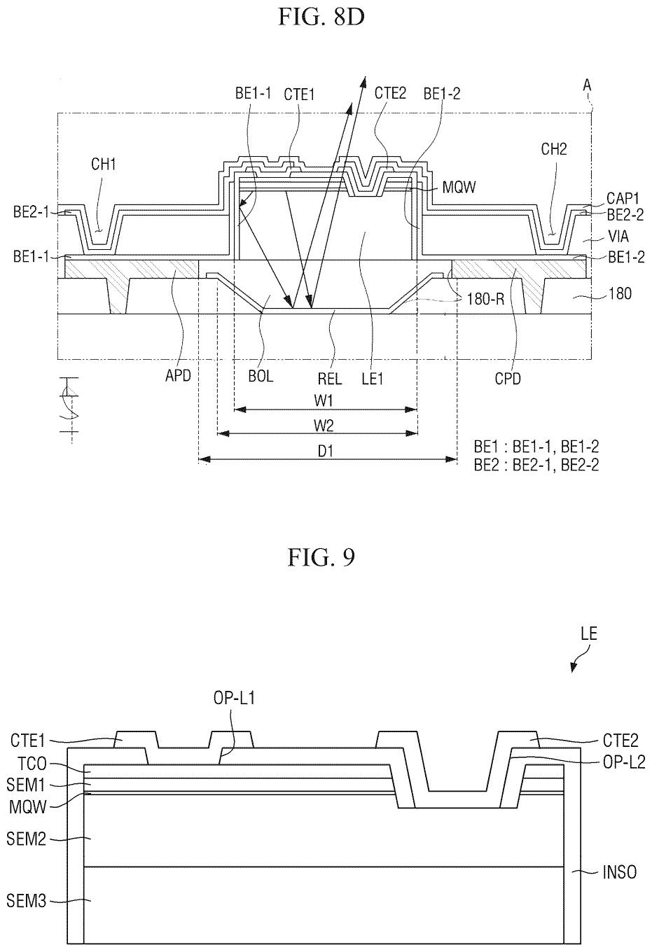

The first light-emitting element LE1 emits light according to the driving current. The amount of light emitted from the first light-emitting element LE1 may be proportional to the driving current. An anode electrode of the first light-emitting element LE1 may be connected to the first electrode of the fourth transistor ST4 and to the second electrode of the sixth transistor ST6 through a first path PH1 and a second path PH2, which is connected in parallel to the first path PH1. A cathode electrode of the first light-emitting element LE1 may be connected to a second power supply line VSL to which the second power voltage is applied through a third path PH3 and a fourth path PH4, which is connected in parallel to the third path PH3. The parallel connection of the anode electrode and the cathode electrode will be described with reference to FIGS. 8 to 10. The first contact electrode CTE1 of the first light-emitting element LE1 described in FIGS. 7 to 10 is an anode electrode, and the second contact electrode CTE2 of the second light-emitting element LE2 is a cathode electrode. In one or more embodiments described with reference to FIGS. 4 and 5, each of the pairs of parallel paths adjacent the anode electrode of the first light-emitting element LE1 and the cathode electrode of the first light-emitting element LE1 is not limited thereto, and the paths adjacent the anode electrode of the first light-emitting element LE1 and the cathode electrode of the first light-emitting element LE1 may be connected in parallel in groups of three or more paths. For example, three paths may be connected in parallel adjacent the anode electrode of the first light-emitting element LE1, and there baths may be connected in parallel adjacent the cathode electrode of the first light-emitting element LE1.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT (e.g., via a turned on first transistor ST1), and the other electrode of the capacitor C1 may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL. The gate electrode of the first transistor ST1 may be connected to the control scan line GCL. The gate electrode of the third transistor ST3 may be connected to the initialization scan line GIL. The gate electrode of the fourth transistor ST4 may be connected to the bias scan line GBL. In one or more embodiments, because the first to sixth transistors ST1, ST2, ST3, ST4, ST5, and ST6 are formed as p-type MOSFET, they may be turned on when a scan signal of the gate low voltage and an emission signal are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to an initialization voltage line VIL.

In addition, the first light-emitting element LE1 may be connected in parallel to each of the anode electrode and the cathode electrode to improve reliability.

FIG. 5 is a circuit diagram illustrating a first sub-pixel of a display panel, according to one or more other embodiments.

Referring to FIG. 5, the driving transistor DT, the second transistor ST2, the fourth transistor ST4, the fifth transistor ST5, and the sixth transistor ST6 are formed as p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the emission line EL, respectively.

Alternatively, the fourth transistor ST4 in FIG. 4 may be formed of the n-type MOSFET, in one or more embodiments. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

Alternatively, in one or more embodiments, the first to sixth transistors ST1, ST2, ST3, ST4, ST5, and ST6 and the driving transistor DT may all be formed as n-type MOSFET.

Meanwhile, the circuit diagram of the second sub-pixel and the third sub-pixel according to one or more embodiments are substantially the same as the circuit diagram of the first sub-pixel SPX1 described in conjunction with FIGS. 4 and 5, so a description thereof will be omitted.

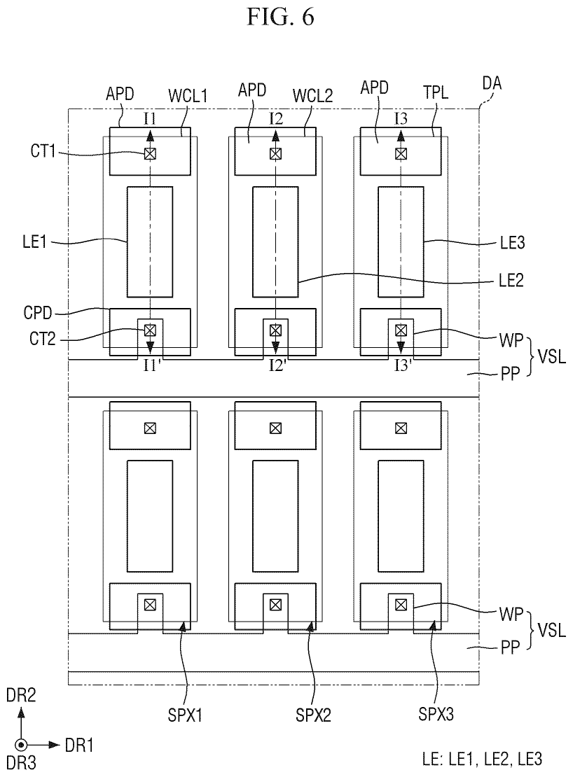

FIG. 6 is a layout diagram illustrating pixels of a display area according to one or more embodiments.

Referring to FIG. 6, each of the plurality of pixels PX in the display area DA may include a first sub-pixel SPX1, a second sub-pixel SPX2, and a third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged in the first direction DR1.

The first sub-pixel SPX1 may emit light of a first color, the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may indicate that the main peak wavelength of the light is included in a wavelength band from about 370 μm to about 460 μm, the green wavelength band may indicate that the main peak wavelength of the light is included in a wavelength band from about 480 μm to about 560 μm, and the red wavelength band may indicate that the main peak wavelength of the light is included in a wavelength band from about 600 μm to about 750 μm.

The first sub-pixel SPX1 includes a first electrode APD, a first light-emitting element LE1, a second electrode CPD, a first connection hole CT1, a second connection hole CT2, and a first light conversion layer WCL1. The second sub-pixel SPX2 includes the first electrode APD, a second light-emitting element LE2, the second electrode CPD, the first connection hole CT1, the second connection hole CT2, and a second light conversion layer WCL2. The third sub-pixel SPX3 includes the first electrode APD, a third light-emitting element LE3, the second electrode CPD, and a light-transmitting layer TPL.

The first electrode APD and the second electrode CPD may be arranged to be spaced apart from each other. Each of the first electrode APD and the second electrode CPD may have a rectangular planar shape. The first electrode APD and the second electrode CPD may have substantially the same area, but embodiments of the present disclosure are not limited thereto.

In one or more embodiments, the area of the first sub-pixel SPX1, the area of the second sub-pixel SPX2, and the area of the third sub-pixel SPX3 are shown as being equal but are not limited thereto. For example, the area of the first sub-pixel SPX1, the area of the second sub-pixel SPX2, and the area of the third sub-pixel SPX3 may be set differently depending on the light conversion efficiency of the first light conversion layer WCL1 and the light conversion efficiency of the second light conversion layer WCL2.

Meanwhile, although it is illustrated that the areas of the first electrode APD and the second electrode CPD of each sub-pixel are the same, the area is not limited to this. For example, depending on the light conversion efficiency of the first light conversion layer WCL1 and the light conversion efficiency of the second light conversion layer WCL2, the areas of the first electrode APD and the second electrode CPD of the second sub-pixel SPX2, and the areas of the first electrode APD and the second electrode CPD of the third sub-pixel SPX3 may be set differently.

In one or more embodiments, each of the plurality of pixels PX includes three sub-pixels, but the present disclosure is not limited thereto, and each of the plurality of pixels PX may include four sub-pixels including a first sub-pixel, a second sub-pixel, a third sub-pixel, and a fourth sub-pixel, and the second sub-pixel and the fourth sub-pixel may emit light of the same color. For example, the first sub-pixel may emit first red light, the second sub-pixel may emit second green light, the third sub-pixel may emit blue light, and the fourth sub-pixel may emit green light. If the pixel PX includes four sub-pixels, for example, the first sub-pixel and the second sub-pixel may be arranged in the first direction DR1, and the first sub-pixel and the third sub-pixel may be arranged in the second direction DR2, and the second sub-pixel and the fourth sub-pixel may be arranged in the second direction DR2.

The area of the first electrode APD may be the same as the area of the second electrode CPD, but embodiments of the present disclosure are not limited thereto.

The first electrode APD may be electrically connected to the second electrode of the fourth transistor (ST4 in FIGS. 4 and 5) and to the second electrode of the sixth transistor (ST6 in FIGS. 4 and 5) of the corresponding sub-pixel SPX1, SPX2, and SPX3 through the first connection hole CT1.

The second electrode CPD may be connected to the second power supply line VSL to which the second driving voltage VSS is applied through the second connection hole CT2. Therefore, the second driving voltage VSS may be applied to the second electrode CPD.

The plurality of light-emitting elements LE may emit the third light, that is, light in the blue wavelength band.

The first light conversion layer WCL1 may completely overlap the first light-emitting element LE1 of the first sub-pixel SPX1. The area of the first light conversion layer WCL1 is larger than the area of the first light-emitting element LE1. The first light conversion layer WCL1 may convert or shift the peak wavelength of incident light into light of another corresponding peak wavelength, and may emit the light. For example, the first light conversion layer WCL1 may convert or shift the third light emitted from the plurality of light-emitting elements LE of the first sub-pixel SPX1 into first light.

The second light conversion layer WCL2 may completely overlap the second light-emitting element LE2 of the second sub-pixel SPX2. The area of the second light conversion layer WCL2 may be larger than the area of the second light-emitting element LE2. The second light conversion layer WCL2 may convert or shift the peak wavelength of incident light into light of another corresponding peak wavelength, and may emit the light. For example, the second light conversion layer WCL2 may convert or shift the third light emitted from the second light-emitting elements LE2 of the second sub-pixel SPX2 into second light.

The light-transmitting layer TPL may completely overlap the third light-emitting element LE3 of the third sub-pixel SPX3. The light-transmitting layer TPL may transmit incident light as it is. For example, the light-transmitting layer TPL may transmit the third light emitted from the third light-emitting element LE3 of the third sub-pixel SPX3 as it is.

The first connection hole CT1 may be an area where the first electrode APD is connected to the fourth source connection electrode SBE4 in FIG. 7, which is electrically connected to a first source area S1 or a first drain area D1 of the first thin film transistor (TFT1 in FIG. 7). The first connection hole CT1 may overlap the first electrode APD.

The second connection hole CT2 may be an area where the second electrode CPD is connected to the second power supply line VSL. The second connection hole CT2 may overlap the second electrode CPD and the second power supply line VSL.

Each of the second power supply lines VSL may be electrically connected to a non-visible power supply line NVSL located in the non-display area NDA as shown in FIG. 2. Each of the second power supply lines VSL may include a wire portion WP extending in the first direction DR1 and a protrusion portion PP projecting from the wire portion WP in the second direction DR2 and overlapping the second connection hole CT2.

FIG. 7 is a cross-sectional view illustrating a cross-section of the display panel taken along the lines I1-I1′, I2-I2′, and I3-I3′ of FIG. 6, according to one or more embodiments. FIG. 8A is a cross-sectional view illustrating one example of area A in FIG. 7 in detail, FIG. 8B is a cross-sectional view illustrating another example of area A in FIG. 7 in detail, FIG. 8C is a cross-sectional view illustrating another example of area A in FIG. 7 in detail, and FIG. 8D is a cross-sectional view illustrating another example of area A of FIG. 7 in detail. FIG. 9 is an enlarged view of the light-emitting element described with reference to FIG. 8A.

Referring to FIGS. 7 and 8A, a substrate SUB may be made of an insulating material, such as glass, polymer resin, or the like. If the substrate SUB is made of polymer resin, it may be a flexible substrate that may be stretched. The polymer resin may be acryl resin, epoxy resin, phenolic resin, polyamide resin, or polyimide resin.

A barrier film BR may be located on (as used herein, “located on” may mean “located above”) the substrate SUB. The barrier film BR is a membrane for protecting the transistors of a thin film transistor layer TFTL and the light-emitting layer of a light-emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, or an aluminum oxide layer.

A first thin film transistor TFT1 may be located on the barrier film BR. The first thin film transistor TFT1 may be either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be located on the barrier film BR. The first active layer ACT1 of the first thin film transistor TFT1 may include polycrystalline silicon, single crystalline silicon, low-temperature polycrystalline silicon, or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be located on one side of the first channel area CHA1, and the first drain area D1 may be located on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate-insulating film 131 may be located on the first channel area CHA1, the first source area S1, and the first drain area D1 of the first thin film transistor TFT1. The first gate-insulating film 131 may be formed of an inorganic film, for example, a silicon nitride layer, a silicon oxynitride layer, a silicon oxide layer, a titanium oxide layer, or an aluminum oxide layer.

A first gate metal layer may be located on the first gate-insulating film 131. The first gate metal layer may include the first gate electrode G1 and a first capacitor electrode CAE1 of the first thin film transistor TFT1. The first gate electrode G1 may overlap the first active layer ACT1 in the third direction DR3. In FIG. 7, the first gate electrode G1 and the first capacitor electrode CAE1 are shown to be located apart from each other, but the first gate electrode G1 and the first capacitor electrode CAE1 may be connected to each other. The first gate metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

A second gate-insulating film 132 may be located on the first gate electrode G1 and the first capacitor electrode CAE1 of the first thin film transistor TFT1. The second gate-insulating film 132 may be formed of an inorganic film, for example, a silicon nitride layer, a silicon oxynitride layer, a silicon oxide layer, a titanium oxide layer, or an aluminum oxide layer.

A second gate metal layer may be located on the second gate-insulating film 132. The second gate metal layer may include a second capacitor electrode CAE2. The second capacitor electrode CAE2 may overlap the first capacitor electrode CAE1 of the first thin film transistor TFT1 in the third direction DR3. Because the second gate-insulating film 132 has a permittivity (e.g., predetermined permittivity), a capacitor (e.g., C1 in FIG. 5) may be formed by the first capacitor electrode CAE1, the second capacitor electrode CAE2, and the second gate-insulating film 132 located between them. The second gate metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

A first interlayer insulating film 141 may be located on the second capacitor electrode CAE2. The first interlayer insulating layer 141 may be formed of an inorganic film, such as a silicon nitride layer, a silicon oxynitride layer, a silicon oxide layer, a titanium oxide layer, or an aluminum oxide layer.

A second thin film transistor TFT2 may be located on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be located on the first interlayer insulating film 141. The second active layer ACT2 may include an oxide semiconductor. For example, the second active layer ACT2 may include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be located on one side of the second channel area CHA2, and the second drain area D2 may be located on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate-insulating film 133 may be located on the second active layer ACT2 of the second thin film transistor TFT2. The third gate-insulating film 133 may be formed of an inorganic film, for example, a silicon nitride layer, a silicon oxynitride layer, a silicon oxide layer, a titanium oxide layer, or an aluminum oxide layer.

A third gate metal layer may be located on the third gate-insulating film 133. The third gate metal layer may include the second gate electrode G2 of the second thin film transistor TFT2. The second gate electrode G2 may overlap the second active layer ACT2 in the third direction DR3. The third gate metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

A second interlayer insulating film 142 may be located on the second gate electrode G2 of the second thin film transistor TFT2. The second interlayer insulating layer 142 may be formed of an inorganic film, for example, a silicon nitride layer, a silicon oxynitride layer, a silicon oxide layer, a titanium oxide layer, or an aluminum oxide layer.

A first data metal layer may be located on the second interlayer insulating film 142. The first data metal layer may include a first source connection electrode SBE3, a second source connection electrode SBE1, and a third source connection electrode SBE2. The first source connection electrode SBE3 may be connected to the first drain area D1 of the first active layer ACT1 through a first source contact hole PCT1 penetrating a first gate-insulating film 131, a second gate-insulating film 132, a first interlayer insulating film 141, a third gate-insulating film 133, and a second interlayer insulating film 142. The second source connection electrode SBE1 may be connected to the second source area S2 of the second active layer ACT2 through a second source connection contact hole BCT1 penetrating the second interlayer insulating film 142. The third source connection electrode SBE2 may be connected to the second drain area D2 of the second active layer ACT2 through a third source connection contact hole BCT2 penetrating the second interlayer insulating film 142. The first data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof. For example, the first data metal layer may include a first layer made of titanium (Ti), a second layer made of aluminum (Al), and a third layer made of titanium (Ti).

A first organic layer 160 may flatten/planarize the step due to the first thin film transistor TFT1 and the second thin film transistor TFT2 on the first source connection electrode SBE3, the second source connection electrode SBE1, and the third source connection electrode SBE2. The first organic layer 160 may be formed from an organic film, such as acrylic resin, epoxy resin, phenolic resin, polyamide resin, polyimide resin, or the like.

A second data metal layer may be located on the first organic layer 160. The second data metal layer may include a fourth source connection electrode SBE4. The fourth source connection electrode SBE4 may be connected to the first source connection electrode SBE3 through a second pixel contact hole PCT2 penetrating the first organic layer 160. The second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof. For example, the second data metal layer may include a first layer made of titanium (Ti), a second layer made of aluminum (Al), and a third layer made of titanium (Ti).

A second organic layer 180 may be located on the fourth source connection electrode SBE4. The second organic layer 180 may be formed of an organic film, such as acrylic resin, epoxy resin, phenolic resin, polyamide resin, polyimide resin, or the like.

The second organic layer 180 may include a recess 180-R. The recess 180-R may overlap an organic pattern layer BOL.

The recess 180-R may overlap the first light-emitting element LE1. A first reflective layer REL may be located on the recess 180-R. The first reflective layer REL may extend from the lower surface of the recess 180-R to the top surface of the second organic layer 180 along an inclined surface, but is located to be spaced apart from the first electrode APD and the second electrode CPD. A width W1 of the recess 180-R may be equal to or wider than a width W2 of the first light-emitting element LE1. The inclined surface of the recess 180-R may be formed vertically as shown in FIG. 8A but is not limited thereto. As shown in FIGS. 8C and 8D, the side surface of the recess 180-R may be formed as an inclined surface. That is, a cup-shaped recess 180-R may be formed in which the lower width of the recess 180-R is less than the upper width of the recess 180-R.

As shown in FIG. 8C, the side surface of the first reflective layer REL located on the recess 180-R also has an inclined surface along the inclined surface of the recess 180-R. In this way, when the first reflective layer REL has an inclined portion, it is suitable to converge light emitted from the light-emitting element LE toward the inclined surface onto the upper side of the light-emitting element LE.

FIG. 8C shows that the upper starting portion of the inclined surface of the first reflective layer REL may coincide with the end of the light-emitting element LE, and as shown in FIG. 8D, the upper starting portion of the inclined surface of the first reflective layer REL may be further outward than the end of the light-emitting element LE. In this case, it may be more effective to converge the light emitted from the light-emitting element LE toward the inclined surface onto the upper side of the light-emitting element LE.

The first reflective layer REL may be formed as a single layer or multiple layers of any one of molybdenum (Mo), aluminum (AI), silver (Ag), platinum (Pt), palladium (Pd), chromium (Cr), gold (Au), titanium (Ti), nickel (Ni), neodymium (Nd), or copper (Cu), or an alloy thereof.

The first reflective layer REL may be formed as a single layer of a highly reflective metal, such as aluminum (AI), or may be formed as a multilayer, such as titanium (Ti)/aluminum (Al)/titanium (Ti) or ITO/aluminum (Al)/ITO. The first reflective layer REL may reflect light emitted from the first light-emitting element LE1 that proceeds in the downward direction of the light-emitting element LE to proceed in the upward direction of the first light-emitting element LE1. Therefore, because light loss from the first light-emitting element LE1 may be reduced, the light efficiency of the first light-emitting element LE1 may be increased.

The light-emitting element layer EML may be located on the second organic layer 180. The light-emitting element layer EML may include a first electrode APD, a second electrode CPD, an organic pattern layer BOL, light-emitting elements LE1, LE2, and LE3, a via layer VIA, a reflective electrode BE1, a connection electrode BE2, and a first capping layer CAP1.

The first electrode APD and the second electrode CPD may be located on the second organic layer 180 to be spaced apart from each other. The first electrode APD and the second electrode CPD may be located on the second organic layer 180 with the recess 180-R interposed therebetween. The recess 180-R may overlap the first light-emitting element LE1 without overlapping the first electrode APD and the second electrode CPD. Referring to FIG. 6, a structure in which the first electrode APD and the second electrode CPD are located on both sides along the short axis direction of the light-emitting element LE is shown, but is not limited thereto, and a structure in which the first electrode APD and the second electrode CPD are located on both sides along a long axis direction of the light-emitting element LE may also be considered.

Each sub-pixel SPX1, SPX2, and SPX3 may include a pair of first electrodes APD and second electrodes CPD. The first electrode APD of each sub-pixel SPX1, SPX2, and SPX3 may be connected to a fourth source connecting electrode SBE4 through a respective connection hole (CT1 in FIG. 6) penetrating the second organic layer 180.

In the first sub-pixel SPX1, the first electrode APD may be connected to the first electrode S1 or the second electrode D1 of the first thin film transistor TFT1 through the first source connection electrode SBE3 and the fourth source connection electrode SBE4. Therefore, a voltage controlled by the first thin film transistor TFT1 in each sub-pixel SPX1, SPX2, and SPX3 may be applied to the first electrode APD. The first electrode APD may be an anode electrode.

The second electrode CPD may be connected to the second power supply line VSL through a second connection hole (CT2 in FIG. 6) penetrating the second organic layer 180. Therefore, the second driving voltage VSS may be applied to the second electrode CPD. The second electrode CPD may be a cathode electrode.

The first electrode APD and the second electrode CPD may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof. In some embodiments, the first electrode APD and the second electrode CPD may have a two-layer structure of Ti/Al or a three-layer structure of Ti/Al/Ti.

The first electrode APD and the second electrode CPD may be arranged to be spaced apart from each other on the same plane, and may be arranged to protrude outwardly from the first light-emitting element LE1. The first electrode APD and the second electrode CPD do not overlap the first light-emitting element LE1.

The first electrode APD and the second electrode CPD may be arranged to be spaced apart from each other by a first separation distance D1. The first separation distance D1 may be greater than the width W2 of the light-emitting element LE. The first separation distance D1 may be from about 4 μm to about 6 μm.

The organic pattern layer BOL is located between the first electrode APD and the second electrode CPD, and may fill the recess 180-R, and may flatten/planarize the step formed by the first electrode APD and the second electrode CPD.

The organic pattern layer BOL serves to temporarily fix or adhere the plurality of light-emitting elements LE to reduce or prevent the likelihood of the plurality of light-emitting elements LE tipping or falling over in the process of transferring the light-emitting elements LE to the display panel 100. That is, the organic pattern layer BOL may be a layer for temporarily adhering the light-emitting element LE to the first electrode APD and the second electrode CPD. To facilitate temporary adhesion, a thickness of the organic layer 210 may be greater than the respective thicknesses of the first electrode APD and the second electrode CPD.

The organic pattern layer BOL may be a photosensitive organic film, such as photoresist. Alternatively, an organic layer 210 may be formed of acrylic resin, epoxy resin, phenolic resin, polyamide resin, polyimide resin, or the like.

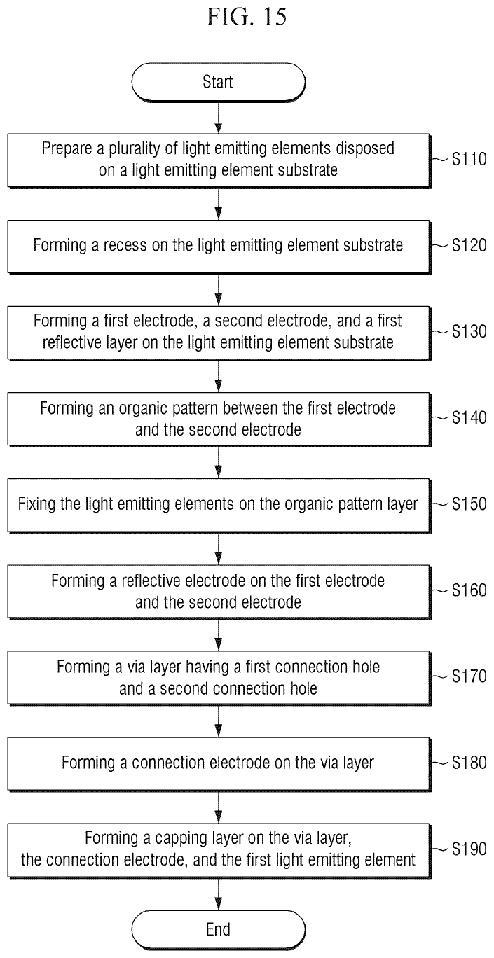

A detailed description of the organic pattern layer BOL will be described later in the manufacturing method of the display device 10 referring to FIGS. 15 to 27.

The light-emitting elements LE may be located on the organic pattern layer BOL. The light-emitting element LE may be flip-type micro-LED. The flip-type micro-LED refers to an LED in which contact electrodes CTE1 and CTE2 are formed on one surface (eg, top surface) of the light-emitting element LE.

Each of the plurality of light-emitting elements LE may be formed of an inorganic material, such as gallium nitride (GaN).

Each of the plurality of light-emitting elements LE may be formed by growing on a semiconductor substrate, such as a silicon substrate or sapphire substrate. The plurality of light-emitting elements LE may be directly transferred from the semiconductor substrate onto the electrodes APD and CPD of the display panel 100. Alternatively, the plurality of light-emitting elements LE may be transferred onto the electrodes APD and CPD of the display panel 100 by an electrostatic method using an electrostatic head or by a stamp method using an elastic polymeric material, such as PDMS or silicone as a transfer substrate.

Referring to FIG. 9, the light-emitting element LE may be a light-emitting structure including a third semiconductor layer SEM3, a second semiconductor layer SEM2, an active layer MQW, a first semiconductor layer SEM1, a transparent conductive layer TCO, a first contact electrode CTE1, and a second contact electrode CTE2.

The third semiconductor layer SEM3 may include an undoped semiconductor and may be a material that is not doped as n-type or p-type. In one or more embodiments, a third semiconductor material layer SEM3 may be at least one of undoped InAlGaN, GaN, AlGaN, InGaN, AlN, or InN, but is not limited thereto.

The second semiconductor layer SEM2 may be located on the third semiconductor layer SEM3. The second semiconductor layer SEM2 may be doped with a second conductive dopant, such as Si, Ge, Sn, or the like. For example, the second semiconductor layer SEM2 may be n-GaN doped with n-type Si. The thickness of the second semiconductor layer SEM2 may be about 500 nm to about 1 μm.

The active layer MQW may be located on the second semiconductor layer SEM2. The active layer MQW may emit light by combining electron-hole pairs according to electrical signals applied through the first semiconductor layer SEM1 and the second semiconductor layer SEM2. The active layer MQW may emit first light having a central wavelength range of about 450 nm to about 495 nm, that is, light in the blue wavelength band.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN but is not limited thereto. The thickness of the well layer may be about 1 nm to about 4 nm, and the thickness of the barrier layer may be about 3 nm to about 10 nm.

Alternatively, the active layer MQW may have a structure in which semiconductor materials having a high band gap energy and semiconductor materials having a low band gap energy are alternately stacked with each other, may include other Group III, IV, or V semiconductor materials according to the wavelength range of emitted light. The light emitted from the active layer MQW is not limited to the first light (light in the blue wavelength band) and may emit second light (light in the green wavelength band) or third light (light in the red wavelength band) in some cases. The thickness of the active layer MQW may be about 10 nm to about 25 nm.

The first semiconductor layer SEM1 may be doped with a first conductive dopant, such as Mg, Zn, Ca, Se, or Ba. For example, the first semiconductor layer SEM1 may be p-GaN doped with p-type Mg. The thickness of the first semiconductor layer SEM1 may be about 30 nm to about 200 nm.

In one or more other embodiments, a superlattice layer may be further included between the active layer MQW and the second semiconductor layer SEM2. The superlattice layer may be a layer for relieving stress between the second semiconductor layer SEM2 and the active layer MQW. The superlattice layer may be formed of InGaN or GaN. In addition, an electron-blocking layer may be further included between the first semiconductor layer SEM1 and the active layer MQW. The electron-blocking layer may be a layer to suppress or reduce or prevent excess electrons flowing into the active layer MQW. For example, the electron-blocking layer may be p-AlGaN doped with p-type Mg. The thickness of the electron-blocking layer may be about 10 nm to about 50 nm. The electronic blocking layer may be omitted.

The transparent conductive layer TCO may be located on the lower surface of the first semiconductor layer SEM1. The transparent conductive layer TCO may be in direct contact with the first semiconductor layer SEM1. The transparent conductive layer TCO may be formed transparently to emit light. The transparent conductive layer TCO may be formed of a transparent conductive oxide, such as indium tin oxide (ITO) or indium zinc oxide (IZO). The transparent conductive layer TCO may be omitted.

An element-insulating layer INSO may be formed to wrap the sides of the third semiconductor layer SEM3, the second semiconductor layer SEM2, the active layer MQW, the first semiconductor layer SEM1, and the transparent conductive oxide TCO and the top surface of the transparent conductive oxide TCO. The element-insulating layer INSO has/defines two openings. For example, the element-insulating layer INSO includes a first opening OP-L1 and a second opening OP-L2. The element-insulating layer INSO may be formed of an inorganic film, for example, a silicon nitride layer, a silicon oxynitride layer, a silicon oxide layer, a titanium oxide layer, or an aluminum oxide layer.

The first contact electrode CTE1 and the second contact electrode CTE2 are located on the two openings. For example, the first contact electrode CTE1 may be located on the first opening OP-L1, and may contact the first semiconductor layer SEM1. The second contact electrode CTE2 may be located on the second opening OP-L2, and may contact the second semiconductor layer SEM2. To this end, the second opening OP-L2 may expose the second semiconductor layer SEM2. The second opening OP-L2 may have a wider diameter than the first opening OP-L1.

The element-insulating layer INS0 may cover the side surfaces of the recess defined by the second opening OP-L2.

Because the first contact electrode CTE1 and the second contact electrode CTE2 are located on the top surface of the light-emitting element LE, they may be transparent electrodes. For example, the first contact electrode CTE1 and the second contact electrode CTE2 may be formed of a transparent conductive oxide, such as indium tin oxide (ITO) or indium zinc oxide (IZO).

In one or more other embodiments, the first contact electrode CTE1 may be a vertical light-emitting element LE located on the upper surface of the light-emitting element LE, and the second contact electrode CTE2 may be a vertical light-emitting element LE located on the lower surface of the light-emitting element LE. When the vertical-type light-emitting element LE is adopted the connection structure may be added or deleted to match the electrode structure depending on the structure of the light-emitting element LE.

Referring again to FIGS. 7 and 8A, the reflective electrode BE1 includes a first reflective electrode BE1-1 in direct contact with the first electrode APD, and a second reflective electrode BE1-2 in direct contact with the second electrode CPD. The first reflective electrode BE1-1 is located on the first electrode APD and extends along the side of the first light-emitting element LE1. The first reflective electrode BE1-1 may be higher than the active layer MQW, but lower than the first light-emitting element LE1. The second reflective electrode BE1-2 is located on the second electrode CPD and extends along the side of the light-emitting element LE. The second reflective electrode BE1-2 may be located higher than the active layer MQW, but lower than the first light-emitting element LE1. That is, the reflective electrode BE1 is not directly located on the first contact electrode CTE1 and the second contact electrode CTE2.

One end of the first reflective electrode BE1-1 and the second reflective electrode BE1-2 may be arranged to be aligned with one end of the first electrode APD and the second electrode CPD but is not limited thereto. Referring to FIG. 8B, one end of the first reflective electrode BE1-1 and the second reflective electrode BE1-2 may be located closer to the light-emitting element LE1 than the first side of the first electrode APD and the second electrode CPD.

When the reflective electrode BE1 is made of a highly reflective metal material, such as aluminum (Al), light emitted from the active layer MQW of the first light-emitting element LE that proceeds in the side direction of the first light-emitting element LE may be reflected from the reflective electrode BE1, and may proceed in the upper direction of the first light-emitting element LE. Therefore, because light loss from the light-emitting element LE may be reduced, the light efficiency of the first light-emitting element LE may be increased. Meanwhile, referring to FIGS. 8A and 8B, the first reflective electrode BE1-1 covers a portion of the side surface of the light-emitting element LE, but is not limited thereto and may cover the entire side surface of the light-emitting element LE.

The via layer VIA flattens/planarizes the step formed by the first light-emitting element LE1. The via layer VIA may be arranged to cover a portion of the side surfaces of the first electrode APD, the second electrode CPD, and the light-emitting element LE. The via layer VIA may cover the reflective electrode BE1, but at least a portion of the reflective electrode BE1 may be exposed without being covered by the via layer VIA. The via layer VIA may be formed from an organic film, such as an acrylic resin, an epoxy resin, a phenolic resin, a polyamide resin, a polyimide resin, or the like.

The via layer VIA may include a plurality of connection holes CH1 and CH2. For example, the via layer VIA may include a first connection hole CH1 formed on the first electrode APD, and a second connection hole CH2 formed on the second electrode CPD. The first connection hole CH1 exposes the first reflective electrode BE1-1 located on the first electrode APD, and the second connection hole CH2 exposes the second reflective electrode BE1-2 located on the second electrode CPD. Alternatively, referring to FIG. 8B, the first connection hole CH1 exposes the first reflective electrode BE1-1 located on the first electrode APD, and the second connection hole CH2 exposes the second electrode CPD.

The via layer VIA supports the connection electrode BE2. The connection electrode BE2 may include a first connection electrode BE2-1 in direct contact with the first contact electrode CTE1, and a second connection electrode BE2-2 in direct contact with the second contact electrode CTE2-2. The first connection electrode BE2-1 and the second connection electrode BE2-2 may be arranged to be spaced apart from each other.

The first connection electrode BE2-1 has one end located on the first contact electrode CTE1, has one end extending along the via layer VIA, and contacts the first reflective electrode BE1 through the first connection hole CH1. In addition, the first connection electrode BE2-1 may extend along the via layer VIA to contact the first reflective electrode BE1-1 at a point where the via layer VIA and the first reflective electrode BE1-1 meet, and may be located on the upper end of the first contact electrode CTE1. Accordingly, the first connection electrode BE2-1 and the first reflective electrode BE1-1 may be in direct contact with the side of the light-emitting element LE.

The second connection electrode BE2-2 has one end located on the second contact electrode CTE2, has one end extending along the via layer VIA, and contacts the second reflective electrode BE1-2 through the second connection hole CH2. In addition, the second connecting electrode BE2-2 may extend along the via layer VIA to contact the second reflective electrode BE1-2 at a point where the via layer VIA and the second reflective electrode BE1-2 meet, and may be located on the upper end of the second contact electrode CTE2. Accordingly, the second connection electrode BE2-2 and the second reflective electrode BE1-2 may be in direct contact with the side of the light-emitting element LE.

A first capping layer CAP1 may cover the via layer VIA, the connection electrode BE2, and the light-emitting element LE. The first capping layer CAP1 may serve to protect the underlying structure. The first capping layer CAP1 may include an inorganic material. For example, the first capping layer CAP1 may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxide.

A wavelength control portion 200 may be located on the light-emitting element layer EML. The wavelength control portion 200 may include a partition wall PW, a second reflective layer RFL, and a wavelength conversion layer QDL.

The partition wall PW is arranged to extend in the first direction DR1 and the second direction DR2, and may be formed in a grid-like pattern throughout the display area DPA. Furthermore, the partition PW may not overlap with the plurality of light-emitting areas EA1, EA2, and EA3, and may overlap with the non-emitting area NEA. The partition wall PW may serve to provide space for the wavelength conversion layer QDL to be formed. The partition wall PW may have a relatively large thickness to provide/define a space for the wavelength conversion layer QDL to be formed. For example, the partition wall PW may include an organic insulating material so that the partition wall PW may be made thick. The organic insulating material may include, for example, epoxy-based resin, acrylic-based resin, cardo-based resin, or imide-based resin.

The partition wall PW may include a first partition wall and a second partition wall that are sequentially stacked. In this case, the length of the first partition wall in the first direction DR1 or the length of the second direction DR2 may be wider than the length of the second partition wall in the first direction DR1 or the length of the second direction DR2. In one or more embodiments, the partition wall PW may block the transmission of light in the non-emitting area NEA. The partition wall PW may further include a light-blocking material and may include a dye or pigment having light-blocking properties. For example, the partition wall PW may include an inorganic black pigment, such as carbon black or an organic black pigment. External light incident on the display device 10 from the outside may cause a problem that distorts the color gamut of the wavelength control portion 200. The partition wall PW including a light-blocking material is located in the wavelength control portion 200 so that at least a portion of external light is absorbed by the light-blocking material. Therefore, color distortion caused by external light reflection may be reduced. Furthermore, the partition wall PW including a light-blocking material may light from intruding between adjacent light-emitting areas and causing mixing, thereby further improving the color reproduction rate.

The second reflective layer RFL may be located between the partition wall PW and the first light conversion layer WCL1, between the partition wall PW and the second light conversion layer WCL2, and between the partition wall PW and the light-transmitting layer TPL. The second reflective layer RFL serves to reflect light traveling in the lateral direction from the first light conversion layer WCL1, the second light conversion layer WCL2, and the light-transmitting layer TPL.

The second reflective layer RFL may include a highly reflective metal material, such as aluminum (Al). The thickness of the second reflective layer RFL may be about 0.1 μm.

Alternatively, the second reflective layer RFL may include M (where M is an integer greater than or equal to 2) pairs of first and second layers having different refractive indices to function as Distributed Bragg Reflectors DBR. In this case, M first layers and M second layers may be arranged alternately. The first layer and the second layer may be formed of an inorganic film, for example, a silicon nitride layer, a silicon oxynitride layer, a silicon oxide layer, a titanium oxide layer, or an aluminum oxide layer.

The wavelength conversion layer QDL may convert or shift the peak wavelength of incident light into light of another corresponding peak wavelength, and may emit the light. The wavelength conversion layer QDL may convert the blue first light emitted from the light-emitting element LE into red second light or green third light, or may transmit the blue first light as it is.

The wavelength conversion layer QDL may be located in each light-emitting area EA1, EA2, and EA3 compartmentalized by the partition wall PW, and may be spaced apart from each other. That is, the wavelength conversion layer QDL may be formed in an island pattern spaced apart from each other. The wavelength conversion layer QDL may overlap the first light-emitting area EA1, the second light-emitting area EA2, and the third light-emitting area EA3, respectively. In one or more embodiments, each of the wavelength conversion layers QDL may completely overlap the first light-emitting area EA1, the second light-emitting area EA2, and the third light-emitting area EA3.

The wavelength conversion layer QDL includes a first wavelength conversion pattern WCL1 overlapping with the first light-emitting area EA1, a second wavelength conversion pattern WCL2 overlapping with the second light-emitting area EA2, and a light transmission pattern TPL overlapping the third light-emitting area EA3.

The first wavelength conversion pattern WCL1 may overlap the first light-emitting area EA1. The first wavelength conversion pattern WCL1 may convert or shift the peak wavelength of incident light into light of another corresponding peak wavelength, and may emit the light. In one or more embodiments, the first wavelength conversion pattern WCL1 may convert and emit blue first light emitted from the light-emitting element LE of the first light-emitting area EA1 into second light, which is red light having a single peak wavelength in the range of about 610 nm to about 650 nm.

The first wavelength conversion pattern WCL1 may include a first base resin BRS1, a first wavelength conversion particle WCP1, and a scatterer SCP. The first base resin BRS1 may include a light-transmitting organic material. For example, the first base resin BRS1 may include epoxy-based resin, acrylic-based resin, cardo-based resin, or imide-based resin.

The first wavelength conversion particle WCP1 may convert the first light incident from the light-emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, or a phosphorescent material. For example, quantum dots may be particulate materials that emit a corresponding color as electrons transition from the conduction band to the valence band.

The quantum dots may be semiconductor nanocrystalline materials. Depending on its composition and size, the quantum dot may have a corresponding bandgap to absorb light, and to emit light with a unique wavelength. Examples of the semiconductor nanocrystals of the quantum dots include Group IV nanocrystals, Group II-VI compound nanocrystals, Group III-V compound nanocrystals, Group IV-VI nanocrystals, or combinations thereof.

The Group II-VI compound may be a binary compound selected from CdSe, CdTe, ZnS, ZnSe, ZnTe, ZnO, HgS, HgSe, HgTe, MgSe, MgS, or mixtures thereof, may be InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or ternary compounds selected from mixtures thereof, or may be a quaternary compound selected from HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof.

The Group III-V compound may be a binary compound selected from GaN, GaP, GaAs, GaSb, AlN, AlP, AlAs, AlSb, InN, InP, InAs, InSb, or mixtures thereof, may be a ternary compound selected from GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or mixtures thereof, or may be a quaternary compound selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof.

The Group IV-VI compounds may be selected from binary compounds selected from SnS, SnSe, SnTe, PbS, PbSe, PbTe, or mixtures thereof, may be ternary compounds selected from SnSeS, SnSeTe, SnSTe, PbSeS, PbSeTe, PbSTe, SnPbS, SnPbSe, SnPbTe, or mixtures thereof, or may be a quaternary compound selected from SnPbSSe, SnPbSeTe, SnPbSTe, or mixtures thereof. The Group IV element may be selected from Si, Ge, or mixtures thereof. The Group IV compound may be a binary compound selected from SiC, SiGe, or mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above, and a shell surrounding the core. The shell of the quantum dot may function as a protective layer to reduce or prevent chemical denaturation of the core to maintain semiconductor properties, and/or as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may be binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds, such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but are not limited thereto.

The second wavelength conversion pattern WCL2 may overlap the second emitting area EA2. The second wavelength conversion pattern WCL2 may emit light by converting or shifting the peak wavelength of incident light into light of another corresponding peak wavelength. In one or more embodiments, the second wavelength conversion pattern WCL2 converts the blue first light emitted from the light-emitting element LE of the second light-emitting area EA2 into green third light having a peak wavelength in the range of about 510 nm to about 550 nm and emit it.

The second wavelength conversion pattern WCL2 may include a second base resin BRS2 and a second wavelength conversion particle WCP2, and may include the scatterer SCP dispersed in the second base resin BRS2.

The second base resin BRS2 may be made of a material with high light transmittance, may be made of the same material as the first base resin BRS1, or may include at least one of the materials provided as their constituent materials.

The second wavelength conversion particle WCP2 may convert or shift the peak wavelength of incident light to another corresponding peak wavelength. In one or more embodiments, the second wavelength conversion particle WCP2 may convert the blue first light provided from the light-emitting element LE into green third light having a peak wavelength in the range of about 510 nm to about 550 nm and emit it. Examples of the second wavelength conversion particle WCP2 include quantum dots, quantum rods, or phosphors. A more detailed description of the second wavelength conversion particle WCP2 is substantially the same as or similar to that described above in the description of the first wavelength conversion particle WCP1 and will be omitted.

The light transmission pattern TPL may be arranged to overlap the third light-emitting area EA3. The light transmission pattern TPL may transmit incident light. The light transmission pattern TPL may directly transmit the blue first light emitted from the light-emitting element LE located in the third light-emitting area EA3. The light transmission pattern TPL may include a third base resin BRS3 and the scatterer SCP dispersed in the third base resin BRS3. Because the third base resin BRS3 is substantially the same as or similar to the above-described first base resin BRS1, description thereof will be omitted.

The wavelength control portion 200 may further include a second capping layer CAP2. The second capping layer CAP2 may be located on the wavelength conversion layer QDL and the partition wall PW. The second capping layer CAP2 may include an inorganic material. For example, the second capping layer CAP2 may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxide. Meanwhile, the drawing illustrates that the second capping layer CAP2 is formed as a single layer, but the present disclosure is not limited thereto. For example, the second capping layer CAP2 may be formed of multiple layers in which inorganic layers containing at least one of the materials that the second capping layer CAP2 may include are alternately stacked. The thickness of the second capping layer CAP2 may range from about 0.05 μm to about 2 μm but is not limited thereto. The second capping layer CAP2 may be located on the top, bottom, and sides of the wavelength conversion layer QDL to surround the wavelength conversion layer QDL to protect the wavelength conversion layer QDL from moisture or moisture. The second capping layer CAP2 may be composed of multiple inorganic films with different refractive indices. Alternatively, the second capping layer CAP2 may include an organic film and have a multilayer structure, for example, an inorganic film/organic film/inorganic film. Alternatively, the second capping layer CAP2 may also be formed of a relatively low refractive index material that has a lower refractive index than the organic layer. When the second capping layer CAP2 is formed of a low refractive index material, total reflection of light emitted from the light-emitting element LE and photo-converted by passing through the wavelength conversion layer QDL may be reduced or prevented. This enables the light to be focused upwards. When the second capping layer CAP2 is formed of multiple layers, for example, when it includes a first capping layer and a second capping layer and the wavelength conversion layer QDL has a refractive index of about 1.5 to about 2.0, at least one of the first capping layer or the second capping layer may have a refractive index between about 1.1 and about 1.5. In another example, if the refractive index of the first overcoat layer OC1 is low, reflection of the light converted through the wavelength conversion layer QDL by the first overcoat layer OC1, resulting in upwardly focused light, may be reduced or prevented.

Meanwhile, the color filter layer CFL may be located on the wavelength control portion 200. The color filter layer CFL may include a first overcoat layer OC1, a first color filter CF1, a second color filter CF2, a third color filter CF3, and a second overcoat layer OC2.

The first overcoat layer OC1 may be located on the wavelength control portion 200. The first overcoat layer OC1 may be directly located on the second capping layer CAP2 of the wavelength control portion 200. The first overcoat layer OC1 may be located entirely over the display area DPA, and may have a flat surface. The first overcoat layer OC1 may flatten/planarize the step formed by the lower wavelength control portion 200 to facilitate the formation of the color filter layer CFL.

The first overcoat layer OC1 may include a light-transmitting organic material. For example, the first overcoat layer OC1 may include epoxy resin, acrylic resin, cardo resin, or imide resin. In one or more other embodiments, the first overcoat layer OC1 may be formed of a low refractive index material that has a lower refractive index than the capping layer CAP or the wavelength conversion layer QDL. When the first overcoat layer OC1 has a low refractive index, reflection of the light, which has been photoconverted through the wavelength conversion layer QDL, by the first overcoat layer OC1, and thereby resulting in light being focused upward, may be reduced or prevented.

In one or more other embodiments, when each light-emitting element LE of each sub-pixel SPX is a native LED, the wavelength control portion 200 may be omitted. That is, the color filter layer CFL may be located on the light-emitting element layer EML.

Alternatively, when each light-emitting element LE of each sub-pixel SPX is a native LED, the wavelength control portion 200 may be implemented to include phosphor particles, rather than a wavelength conversion material, to improve light purity.

The first color filter CF1, the second color filter CF2, and the third color filter CF3 may be located on the first overcoat layer OC1. The first color filter CF1 may be located in the first emitting area EA1, the second color filter CF2 may be located in the second emitting area EA2, and the third color filter CF3 may be located in the third emitting area EA3.

The first color filter CF1, the second color filter CF2, and the third color filter CF3 may include a colorant, such as the dye or pigment that absorbs wavelengths other than the corresponding color wavelength. The first color filter CF1 may selectively transmit the second light (e.g., red light), and may block or absorb the first light (e.g., blue light) and the third light (e.g., green light). The second color filter CF2 may selectively transmit the third light (e.g., green light), and may block or absorb the first light (e.g., blue light) and the second light (e.g., red light). The third color filter CF3 may selectively transmit the first light (e.g., blue light), and may block or absorb the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to the top of the substrate SUB to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may reduce or prevent color distortion due to reflection of external light. Additionally, the first color filter CF1, the second color filter CF2, and the third color filter CF3 may serve to block external light. For example, the first color filter CF1 located in the first sub-pixel SPX1 may reduce or prevent color mixing by blocking the second color light and the third color light coming from the outside. The color purity of sub-pixels may be improved.

The plane area of each of the first color filter CF1, the second color filter CF2, and the third color filter CF3 may be larger than the planar area of each of the plurality of light-emitting areas EA1, EA2, and EA3. For example, the first color filter CF1 may be larger than the planar area of the first emitting area EA1. The second color filter CF2 may be larger than the planar area of the second emitting area EA2. The third color filter CF3 may be larger than the planar area of the third emitting area EA3. However, it is not limited thereto, and the planar area of each of the first color filter CF1, the second color filter CF2, and the third color filter CF3 may be equal to the planar area of each of the plurality of light-emitting areas EA1, EA2, and EA3. In one or more other embodiments, the planar areas of each of the first color filter CF1, second color filter CF2, and third color filter CF3 may be different. For example, the second color filter CF2 may have the largest area, the third color filter CF3 may have the smallest area, and the first color filter CF1 may have an area intermediate between the area of the second color filter CF2 and the area of the third color filter CF3. For example, the first color filter CF1, the second color filter CF2, and the third color filter CF3 may be red, green, and blue, respectively.

The second overcoat layer OC2 may be located on the first color filter CF1, the second color filter CF2, and the third color filter CF3. The second overcoat layer OC2 may be directly located on the first color filter CF1, the second color filter CF2, and the third color filter CF3. The second overcoat layer OC2 may be located entirely in the display area DPA and may have a flat surface. The second overcoat layer OC2 may flatten/planarize the step formed by the first color filter CF1, the second color filter CF2, and the third color filter CF3 at the bottom. The second overcoat layer OC2 may include a light-transmitting organic material and may be substantially the same as or similar to the first overcoat layer OC1 described above.

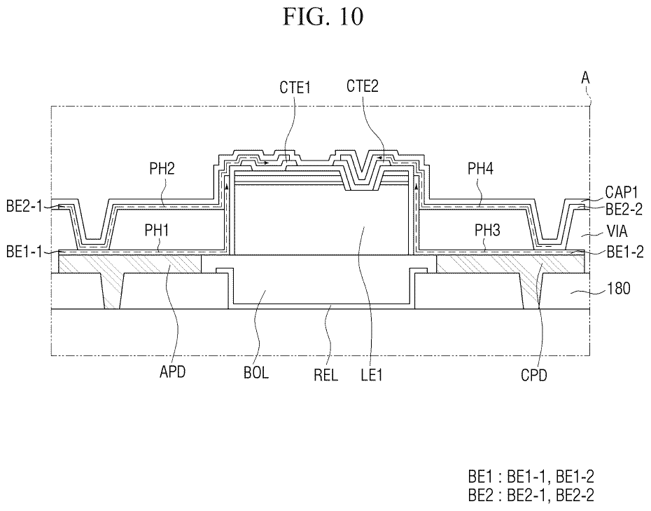

FIG. 10 is a diagram to illustrate a contact path between a first electrode and a first contact electrode in the display panel illustrated with reference to FIG. 8A.

Referring to FIG. 10, a path for supplying a second power to the first light-emitting element LE1 is a first contact path PH1 through the first reflective electrode BE1-1 and a second contact path PH2 through the first connection electrode BE2-1.

In addition, the path for supplying the voltage controlled by the first thin film transistor TFT1 in FIG. 7 to the first light-emitting element LE1 may include a third contact path PH3 through the second reflective electrode BE1-2 and a fourth contact path PH2 through the second connection electrode BE2-2.

In this way, when there are two contact paths between the first contact electrode CTE1 and the first electrode APD, and two contact paths between the second contact electrode CTE2 and the second electrode CPD, it is possible to inject current into the light-emitting element LE through the other, even if a break occurs in one of the contact paths.

In addition, when the first contact electrode CTE1 and the first electrode APD of the first light-emitting element LE1 are connected in parallel, and the second contact electrode CTE2 and the second electrode CPD of the first light-emitting element LE1 are connected in parallel, there is resistance reduction compared to a series connection.

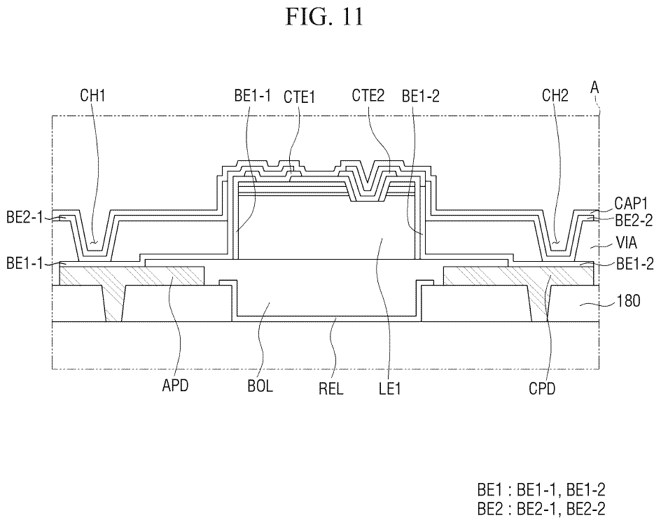

FIG. 11 is a cross-sectional view illustrating another example of area A of FIG. 7 in detail.

The one or more embodiments corresponding to FIG. 11 differ from the one or more embodiments corresponding to FIG. 8 in that the reflective electrode BE1 is in direct contact with the first contact electrode CTE1 and the second contact electrode CTE2. In the one or more embodiments corresponding to FIG. 11, descriptions overlapping with those of FIGS. 7 and 8 are omitted.

The reflective electrode BE1 may include a first reflective electrode BE1-1 in direct contact with the first electrode APD, and a second reflective electrode BE1-2 in direct contact with the second electrode CPD. The first reflective electrode BE1-1 is located on the first electrode APD and extends along the side of the first light-emitting element LE1 to directly contact the first contact electrode CTE1. The second reflective electrode BE1-2 is located on the second electrode CPD and extends along the side of the first light-emitting element LE1 to directly contact the second contact electrode CTE2.

On the other hand, the first connection electrode BE2-1 is located on the via layer VIA and contacts the first reflective electrode BE1-1 through the first connection hole CH1, and extends along the side of the first light-emitting element LE1. The first connection electrode BE2-1 may directly contact the first reflective electrode BE1-1 on the side of the first light-emitting element LE1.

In addition, the second connection electrode BE2-2 is located on the via layer VIA to contact the second reflective electrode BE1-2 through the second connection hole CH2, and extends to the side of the first light-emitting element LE1. The second connection electrode BE2-2 may directly contact the second reflective electrode BE1-2 on the side of the first light-emitting element LE1.

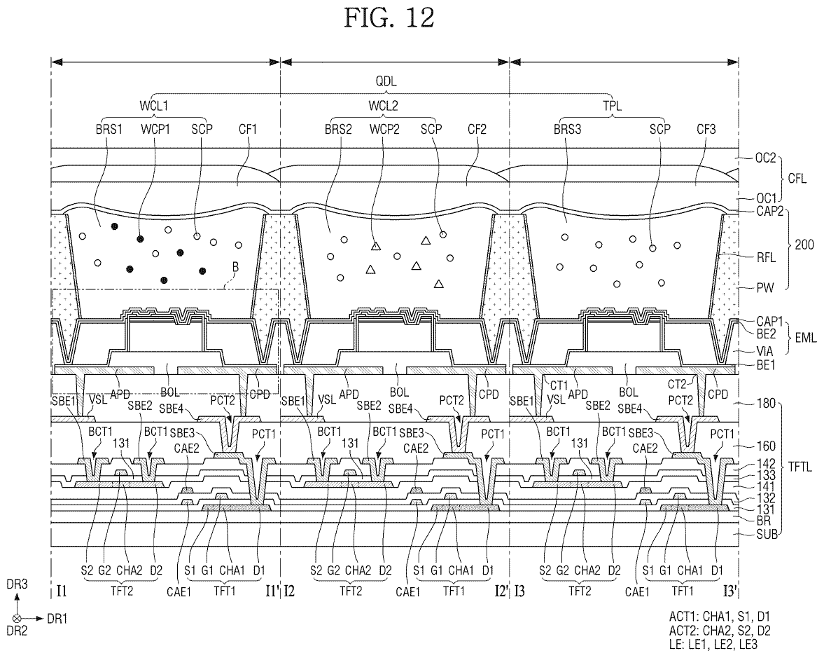

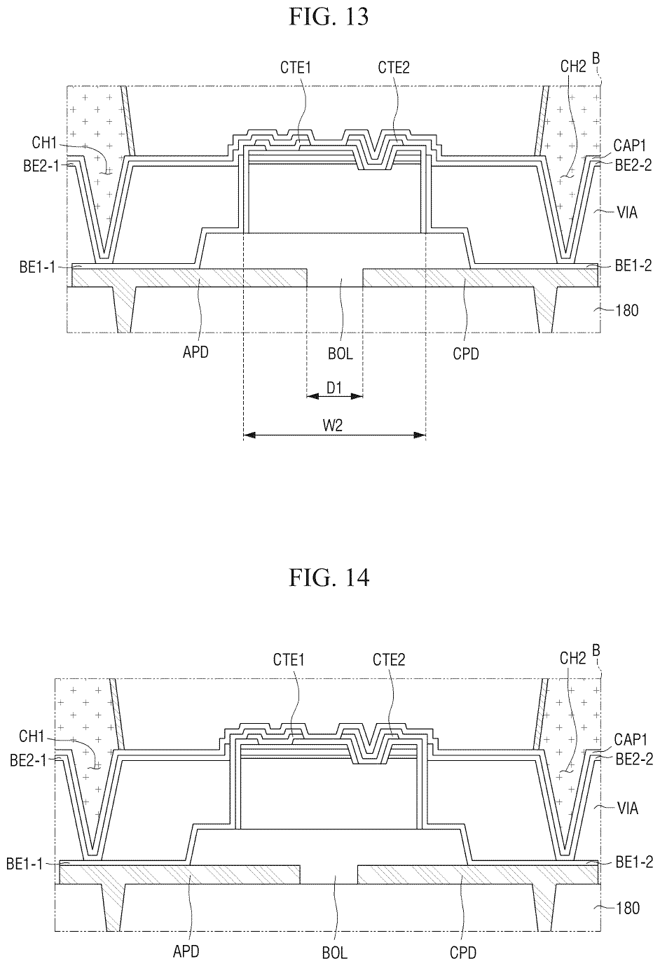

FIG. 12 is a cross-sectional view illustrating another example of a cross-section of the display panel taken along the lines I1-I1′, I2-I2′, and I3-I3′ of FIG. 6. FIG. 13 is a cross-sectional view illustrating one example of area B of FIG. 12 in detail.

The one or more embodiments corresponding to FIGS. 12 and 13 differs from the one or more embodiments corresponding to FIGS. 7 and 8 in that the second organic layer 180 does not have a recess 180-R and a first reflective layer REL, in that the first electrode APD and the second electrode CPD partially overlap the light-emitting element LE, and in that the reflective layer RFL is located along the recess 180-R. In the embodiments of FIGS. 12 and 13, descriptions overlapping with those of FIGS. 7 and 8 will be omitted.

The first electrode APD and the second electrode CPD may be spaced apart from each other on the same plane of the second organic layer 180, and may protrude outwardly from the light-emitting element LE. The first electrode APD and the second electrode CPD may be arranged to be spaced apart from each other by a first separation distance D1. The first separation distance D1 may be less than the width W2 of the light-emitting element LE. Therefore, by making the first separation distance D1 less than the width W2 of the light-emitting element LE, as shown in FIG. 13, light leaking from the bottom of the light-emitting element LE may be reduced or minimized without placing a separate reflective layer between the first electrode APD and the second electrode CPD.

FIG. 14 is a cross-sectional view illustrating another example of area B in FIG. 12 in detail.

The one or more embodiments corresponding to FIG. 14 differs from the one or more embodiments corresponding to FIG. 13 in that the reflective electrode BE1 directly contacts the first contact electrode CTE1 and the second contact electrode CTE2. In the one or more embodiments corresponding to FIG. 14, descriptions overlapping with those of FIGS. 12 and 13 are omitted.

Referring to FIG. 14, the reflective electrode BE1 may include a first reflective electrode BE1-1 in direct contact with the first electrode APD, and a second reflective electrode BE1-2 in direct contact with the second electrode CPD. The first reflective electrode BE1-1 is located on the first electrode APD, and extends along the side of the first light-emitting element LE1 to directly contact the first contact electrode CTE1. The second reflective electrode BE1-2 is located on the second electrode CPD, and extends along the side of the first light-emitting element LE1 to directly contact the second contact electrode CTE2.

On the other hand, the first connection electrode BE2-1 is located on the via layer VIA, contacts the first reflection electrode BE1-1 through the first connection hole CH1, and extends along the side of the first light-emitting element LE1. The first connection electrode BE2-1 may directly contact the first reflective electrode BE1-1 on the side of the first light-emitting element LE1.

In addition, the second connection electrode BE2-2 is located on the via layer VIA to contact the second reflective electrode BE1-2 through the second connection hole CH2, and extends to the side of the first light-emitting element LE1. The second connection electrode BE2-2 may directly contact the second reflective electrode BE1-2 on the side of the first light-emitting element LE1. FIG. 15 is a flowchart illustrating a method of manufacturing a display device

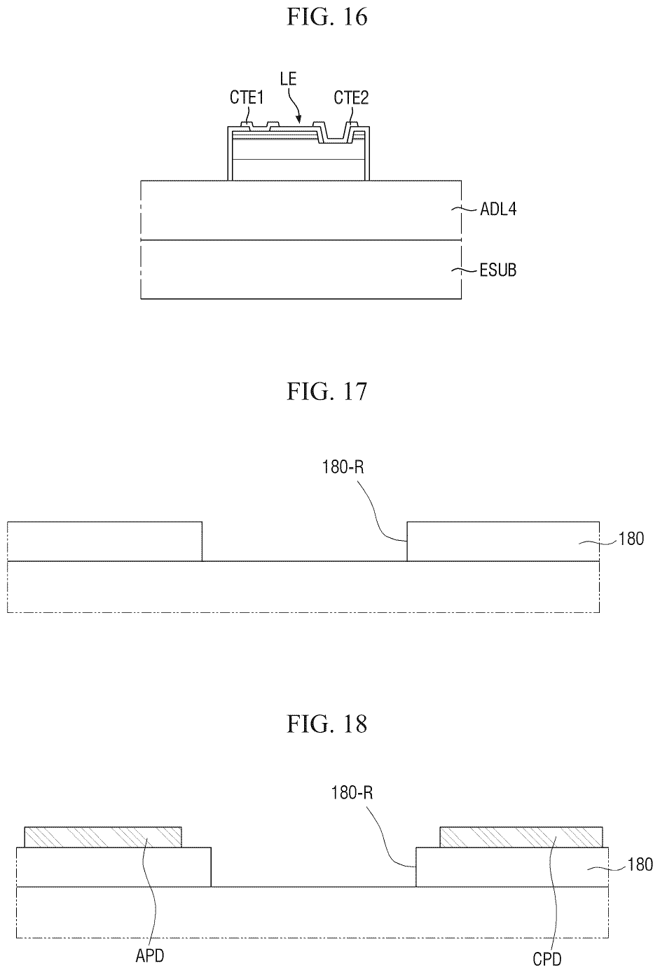

according to one or more embodiments. FIGS. 16 to 27 are cross-sectional views to illustrate a method of manufacturing a display device according to one or more embodiments. FIGS. 17 to 27 illustrate examples of cross sections of the display panel taken along the line I1-I1′ in FIG. 7. Some of the drawings in FIGS. 18 to 26 show plan views corresponding to cross sections together. Further, the following illustrations will focus on the first light-emitting area EA1 of the display device 10.

First, as shown in FIG. 16, a plurality of light-emitting elements LE arranged on a light-emitting element substrate ESUB may be prepared (S110 in FIG. 15).

The first light-emitting element LE1 is located on a fourth adhesive layer ADL4 located on the light-emitting element substrate ESUB. The plurality of light-emitting elements LE are fixed by adhesion to the fourth adhesive layer ADL4. The light-emitting element substrate ESUB may include a material that allows light to be transmitted. For example, the light-emitting element substrate ESUB may include transparent polymers, such as polyimide, polyester, polyacrylic, polyepoxy, polyethylene, polystyrene, polyethylene terephthalate, or the like. The fourth adhesive layer ADL4 may include an adhesive material for bonding the plurality of light-emitting elements LE. For example, the adhesive material may include urethane acrylate, epoxy acrylate, polyester acrylate, and the like.

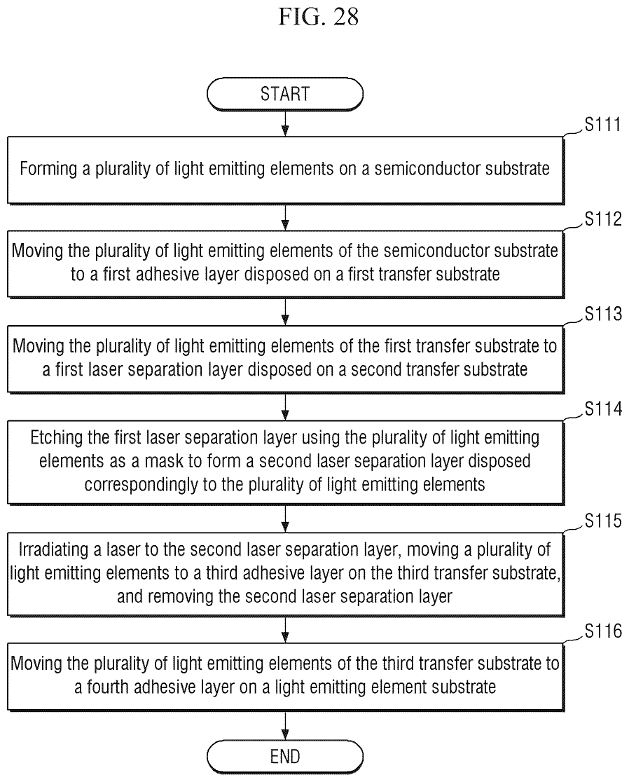

A detailed description of a method of transferring the plurality of light-emitting elements LE formed on the semiconductor substrate SSUB onto the light-emitting element substrate ESUB will be described later with reference to FIGS. 28 to 35.

Second, as shown in FIG. 17, a recess 180-R may be formed by using a mask MSK on the substrate SUB having a thin film transistor layer (TFTL in FIG. 7) (S120 in FIG. 15).

The substrate having the thin film transistor layer may include a second organic layer 180 on the top surface. The recess 180-R is formed on the second organic layer 180 using a photolithography process.

Third, as shown in FIGS. 18 and 19, a first electrode APD, a second electrode CPD, and a first reflective layer REL are formed on the second organic layer 180 having the recess 180-R (S130 in FIG. 15).

An electrode material layer is applied on the second organic layer 180 having the recess 180-R. Then, using a photolithography process, the first electrode APD and the second electrode CPD are formed to be spaced apart from each other on the same plane with the recess 180-R in between.

Thereafter, a first reflective layer REL is formed on the top and side surfaces of the recess 180-R using a photolithography process. The first reflective layer REL is formed to be spaced apart from the first electrode APD and the second electrode CPD.

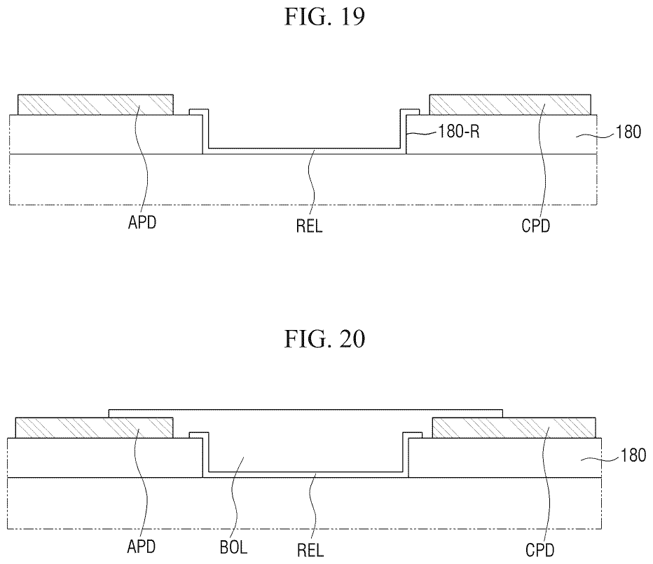

Fourth, as shown in FIG. 20, an organic pattern layer BOL is formed between the first electrode APD and the second electrode CPD (S140 in FIG. 15).

The organic pattern layer BOL may be formed to cover the edges of the first electrode APD and the edges of the second electrode CPD. The organic pattern layer BOL may be filled in the space spaced apart between the first electrode APD and the second electrode CPD. The organic pattern layer BOL may be formed to be thicker than the height of the first electrode APD and the second electrode CPD.

The organic pattern layer BOL may be a temporary adhesive layer, or temporary fixation layer, which serves to temporarily fix or adhere the plurality of light-emitting elements LE in the process of transferring the light-emitting elements LE to the display panel 100.

The organic pattern layer BOL may be a photosensitive organic film, such as photoresist. Alternatively, the organic pattern layer BOL may be formed of acryl resin, epoxy resin, phenolic resin, polyamide resin, a polyimide resin, or the like.

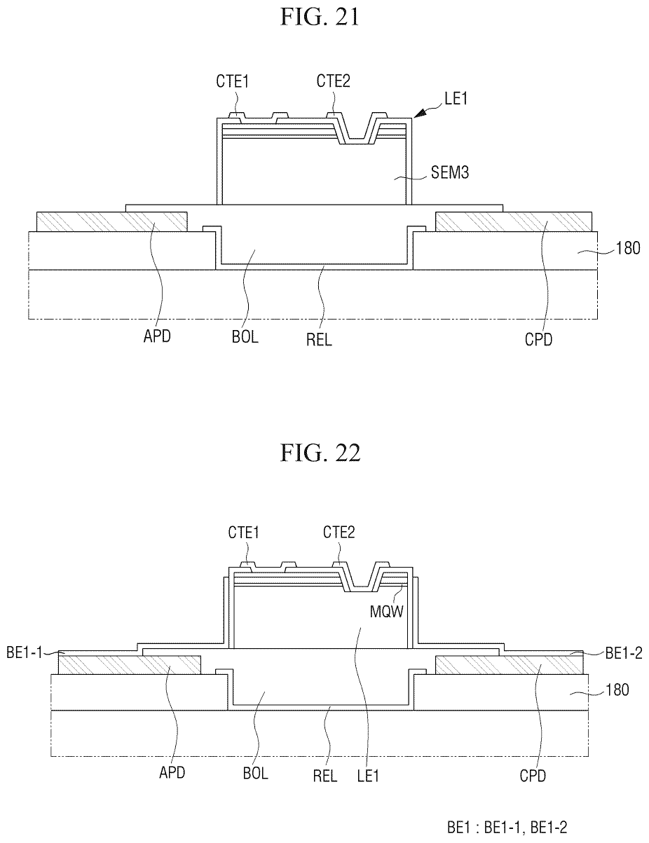

Fifth, as shown in FIG. 21, a plurality of light-emitting element LE of the light-emitting element substrate ESUB are fixed to the organic pattern layer BOL (S150 in FIG. 15).

The light-emitting element LE on the light-emitting element substrate ESUB may be located on the organic pattern layer BOL. The light-emitting element LE may be located so that the first contact electrode CTE1 and the second contact electrode CTE2 are facing the upper surface. The first contact electrode CTE1 may be located close to the first electrode APD, and the second contact electrode CTE2 may be located close to the second electrode CPD.

At this time, the plurality of light-emitting elements LE may be temporarily fixed by being embedded in the organic pattern layer BOL. For example, the third semiconductor layer SEM3 of each of the plurality of light-emitting elements LE may be embedded in the organic pattern layer BOL and may be fixed.

If the organic pattern layer BOL is a photosensitive organic film, such as a photoresist, the organic pattern layer BOL may be cured (soft baked) at a first temperature, and then at least a portion of the first light-emitting element LE1 may be inserted into the organic pattern layer BOL. Then, the organic pattern layer BOL may be completely cured at a second temperature that is higher than the first temperature. The first temperature may be approximately 100 degrees, and the second temperature may be approximately 230 degrees, but embodiments of the present specification are not limited thereto. In the process of curing the organic pattern layer BOL at the first temperature, the organic pattern layer BOL may be fluid because the first temperature is low enough to fully cure the organic pattern layer BOL. If the organic pattern layer BOL spreads over a larger area than suitable, the organic pattern layer may be formed into a suitable shape by etching or ashing after an additional curing process to be described later. Furthermore, the process of completely curing the organic pattern layer BOL at the second temperature may be performed for approximately 30 minutes.

Then, the light-emitting element substrate ESUB is separated from the first light-emitting element LE1. For example, ultraviolet light or heat may be applied to the adhesive layer of the light-emitting element substrate ESUB to reduce the adhesion of the adhesive layer of the light-emitting element substrate ESUB, and then the light-emitting element substrate ESUB may be physically or naturally separated from the plurality of light-emitting elements LE.

Sixth, as shown in FIG. 22, a reflective electrode BE1 is formed using a photolithography process (S160 in FIG. 15).

The first reflective electrode BE1-1 is formed to extend along the side of the first light-emitting element LE1 on the first electrode APD. The second reflective electrode BE1-2 is formed to extend along the side of the first light-emitting element LE1 on the second electrode CPD. The first reflective electrode BE1-1 and the second reflective electrode BE1-2 are located higher than the active layer MQW of the light-emitting element LE.

For example, a reflective electrode material is deposited on the first electrode APD, the second electrode CPD, and the first light-emitting element LE1. Then, the first reflective electrode BE1-1 and the second reflective electrode BE1-2 spaced apart from each other are formed using a photoresist technique using a mask.

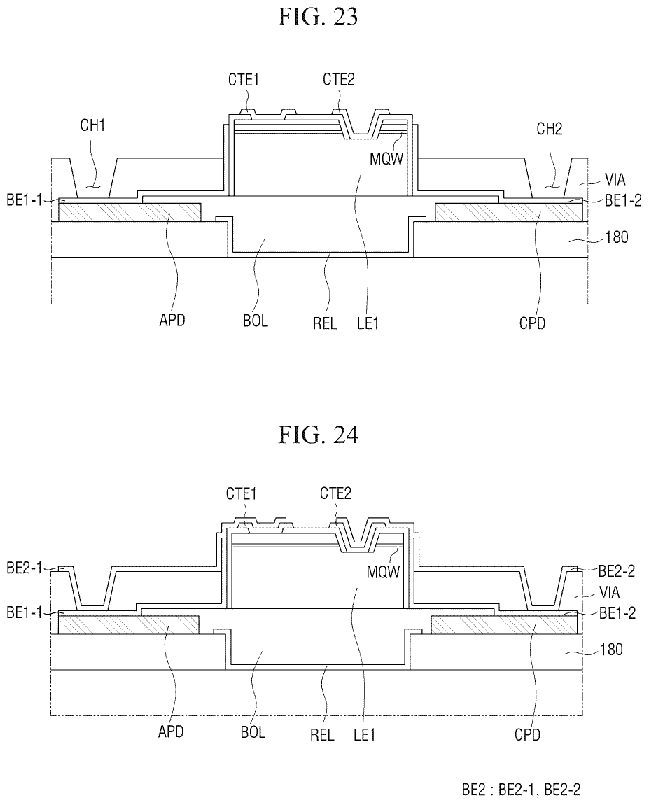

Seventh, as shown in FIG. 23, a via layer VIA having a first connection hole CH1 and a second connection hole CH2 is formed (S170 in FIG. 15).

The via layer VIA may be formed lower than the height of the active layer MQW of the light-emitting element LE. The via layer VIA may be applied using a solution process, such as spin coating, inkjet printing, or the like.

Next, a plurality of connection holes CH1 and CH2 are formed in the via layer VIA through an etching process using a mask.

The first connection hole CH1 exposes the first electrode APD on the first electrode APD, and the second connection hole CH2 exposes the second electrode CPD on the second electrode CPD.

Eighth, as shown in FIG. 24, a connection electrode BE2 is formed on the via layer VIA (S180 in FIG. 15).

A layer of connection electrode material is deposited on the via layer VIA. Then, a first connection electrode BE2-1 and a second connection electrode BE2-2 spaced apart from each other are formed using a photoresist technique using a mask.

The first connection electrode BE2-1 contacts the first contact electrode CTE1 of the first light-emitting element LE1 and the first reflective electrode BE1-1 exposed by the first connection hole CH1 in each of the sub-pixels SPX1, SPX2, and SPX3, and the second connection electrode BE1-2 contacts the second electrode CPD exposed by the second connection hole CH2.

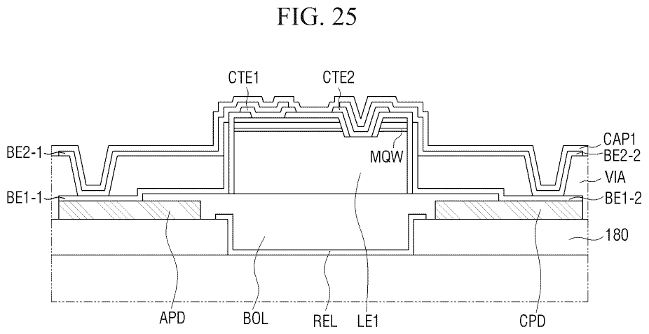

Ninth, as shown in FIG. 25, a capping layer CAP is formed on the via layer VIA, the connection electrode BE2, and the first light-emitting element LE1 (S190 in FIG. 15).

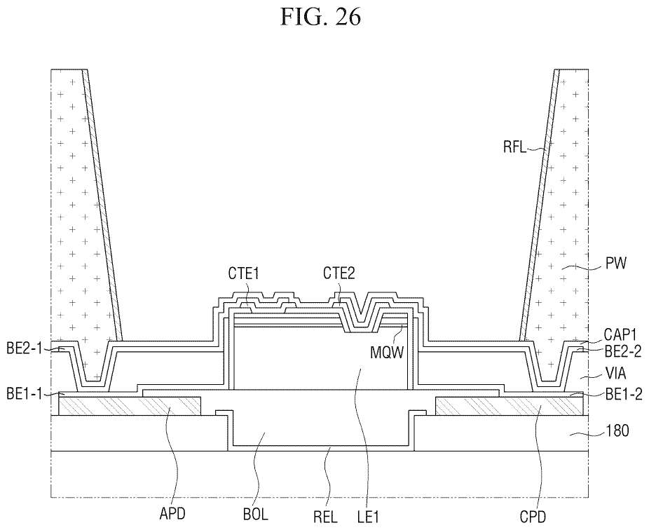

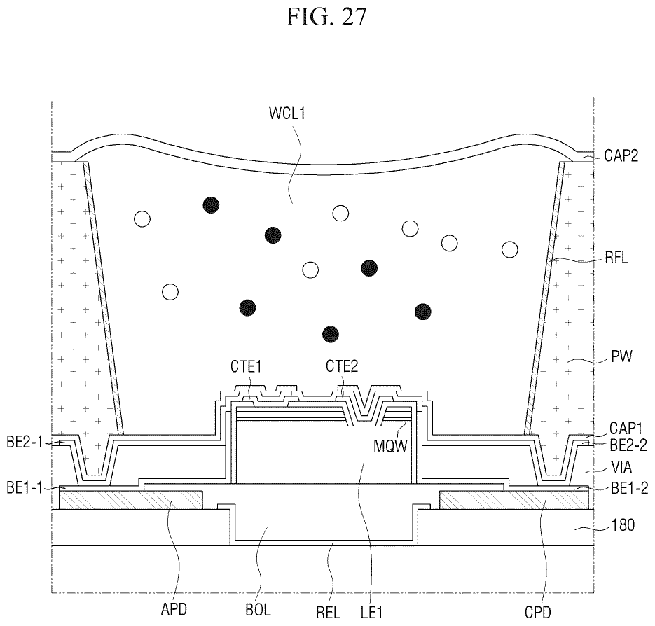

Tenth, as shown in FIGS. 26 and 27, a partition wall PW, a second reflective layer RFL, a wavelength conversion layer WCL1, and a light transmission layer TPL are formed. Further, a color filter layer (CFL in FIG. 7) may be formed.

First, an organic material is applied to the via layer VIA and patterned to form a partition wall PW. A second reflective layer RFL2 may be formed on the inner surface of the space formed by the partition wall PW.

Then, the partition wall PW has an opening, and a wavelength conversion layer WCL1 is formed in the opening. Among the areas compartmentalized by the partition wall PW, a first wavelength conversion layer WCL1 is formed in the first sub-pixel SPX1, a second wavelength conversion layer WCL2 is formed in the second sub-pixel SPX2, and a light transmission layer TPL is formed in the third sub-pixel SPX3.

Then, the first overcoat layer OC1, first color filter CF1, second color filter CF2, third color filter CF3, and second overcoat layer OC2 described in FIG. 7 may be formed on the partition wall PW, wavelength conversion layer WCL1 and WCL2, and light transmission layer TPL.

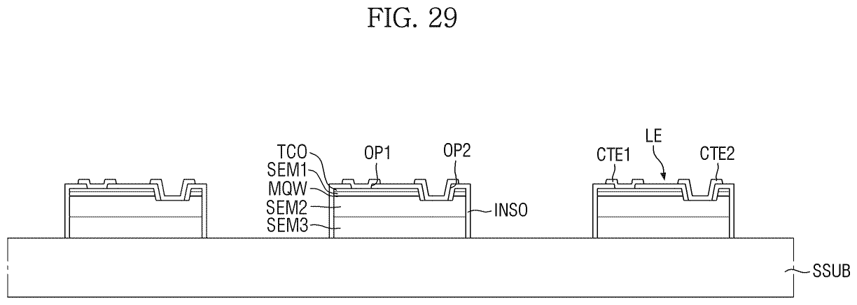

FIG. 28 is a flowchart illustrating operation S110 of FIG. 15 in detail. FIGS. 29 to 35 are cross-sectional views to illustrate operation S110.

Hereinafter, the process of transferring the plurality of light-emitting elements LE formed on the semiconductor substrate SSUB to the light-emitting element substrate ESUB will be described in detail with reference to FIGS. 28 to 35.

First, a plurality of light-emitting elements LE may be formed on the semiconductor substrate SSUB as shown in FIG. 29 (S111 in FIG. 28).

The semiconductor substrate SSUB may be a silicon wafer substrate or a sapphire substrate. A light-emitting element material layer may be deposited on the entire semiconductor substrate SSUB. The light-emitting element material layer may be formed on the semiconductor substrate SSUB through an epitaxial growth process. As the epitaxial growth process, the methods of forming the light-emitting element material layer may include electron beam deposition, physical vapor deposition (PVD), chemical vapor deposition (CVD), plasma laser deposition (PLD), dual-type thermal evaporation, sputtering, metal organic chemical vapor deposition (MOCVD), and the like. For example, metal-organic chemical vapor deposition (MOCVD) may be used, but the embodiments of the present specification are not limited thereto.

Next, a transparent conductive material layer is formed on the light-emitting element material layer. Then, the plurality of semiconductor material layers and the transparent conductive material layer are etched. As shown in FIG. 9, the light-emitting element material layer may include a third semiconductor layer SEM3, a second semiconductor layer SEM2, an active layer MQW, and a first semiconductor layer SEM1.

Then, after forming a mask pattern on the light-emitting element material layer, the light-emitting element material layer and the transparent conductive material layer may be etched according to the mask pattern to form the plurality of light-emitting elements LE. The mask pattern may be removed after forming the plurality of light-emitting elements LE.

The light-emitting element material layer may be etched by dry etching, wet etching, reactive ion etching (RIE), deep reactive ion etching (DRIE), inductively coupled plasma reactive ion etching (ICP-RIE), or the like. The dry etching allows for anisotropic etching and may be suitable for vertical etching. In the case of dry etching, the etching gas may be Cl₂ or O₂, but is not limited thereto.

Then, an opening exposing the second semiconductor layer SEM2 on the transparent conductive material layer TCOL is formed by an etching process. As described above, the etching process may be a dry etching method, a wet etching method, a reactive ion etching (RIE) method, a deep reactive ion etching (DRIE) method, an inductively coupled plasma reactive ion etching (ICP-RIE) method, or the like.

Next, an insulating material layer having a plurality of openings OP1 and OP2 may be formed on the base substrate BSUB on which the light-emitting element LE is formed.

Then, a second etch (2^{nd} etch) may be performed to partially remove the insulating material layer to form the light-emitting element LE including an element-insulating layer INS0.

For example, a second etch (2^{nd} etch) process may be performed in which the insulating material layer may be partially removed such that the insulating material layer exposes the top surface of the light-emitting element LE and surrounds the sides of the light-emitting element LE. For example, in this process, the insulating material layer may remove at least a portion of the top surface of the transparent conductive layer TCO of the light-emitting element LE to define a first opening OP1. Further, the insulating material layer may define the second opening OP2 by removing at least a portion of the second semiconductor layer SEM2 of the light-emitting element LE. The process of partially removing the insulating material layer may be performed by an etching process using a mask.

Next, a first contact electrode CTE1 in the first opening OP1 and a second contact electrode CTE2 in the second opening OP2 may be formed on the light-emitting element LE.

For example, the first contact electrode CTE1 and the second contact electrode CTE2 may be formed by laminating a contact electrode material layer on the base substrate BSUB. Afterwards, the contact electrode material layer is etched by an etching process to form the first contact electrode CTE1 covering the first opening OP1 of the light-emitting element LE and the second contact electrode CTE2 covering the second opening OP2. The contact electrode material layer may be formed of a transparent conductive material. For example, the contact electrode material layer may be a transparent conductive oxide, such as indium tin oxide (ITO) or indium zinc oxide (IZO).

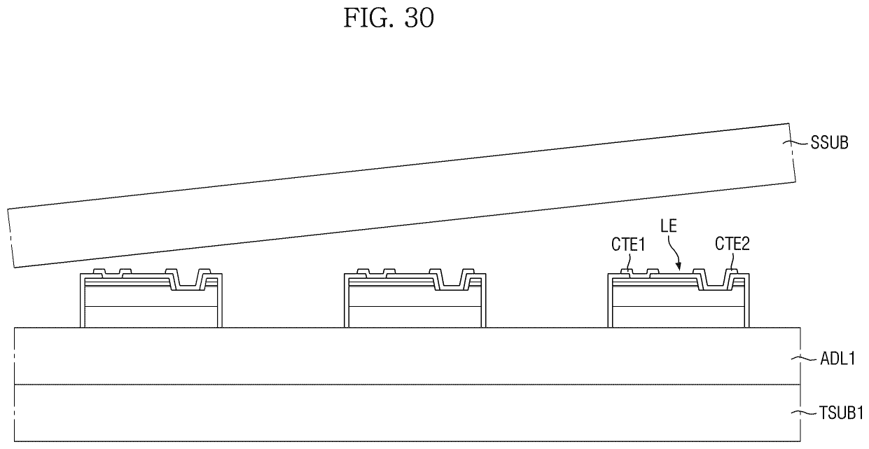

Second, as shown in FIG. 30, the plurality of light-emitting elements LE of the semiconductor substrate SSUB may be moved to a first adhesive layer ADL1 located on a first transfer substrate TSUB1 (S112 in FIG. 28).

The first transfer substrate TSUB1 may be made of a transparent material to allow light to pass through. For example, the first transfer substrate TSUB1 may include a transparent polymer, such as polyimide, polyester, polyacrylic, polyepoxy, polyethylene, polystyrene, polyethylene terephthalate, or the like. The first adhesive layer ADL1 located on one surface of the first transfer substrate TSUB1 may include an adhesive material for bonding the plurality of light-emitting elements LE. For example, the adhesive material may include urethane acrylate, epoxy acrylate, polyester acrylate, and the like.

The first contact electrode CTE1 and the second contact electrode CTE2 of each of the plurality of light-emitting elements LE may be bonded to the first adhesive layer ADL1 located on the first transfer substrate TSUB1. Then, the plurality of light-emitting elements LE may be separated from the semiconductor substrate SSUB by a laser lift off (LLO) process in which the semiconductor substrate (SSUB) is irradiated with a laser. The laser may be a KrF excimer laser having a wavelength of about 248 nm, but embodiments of the present specification are not limited thereto.

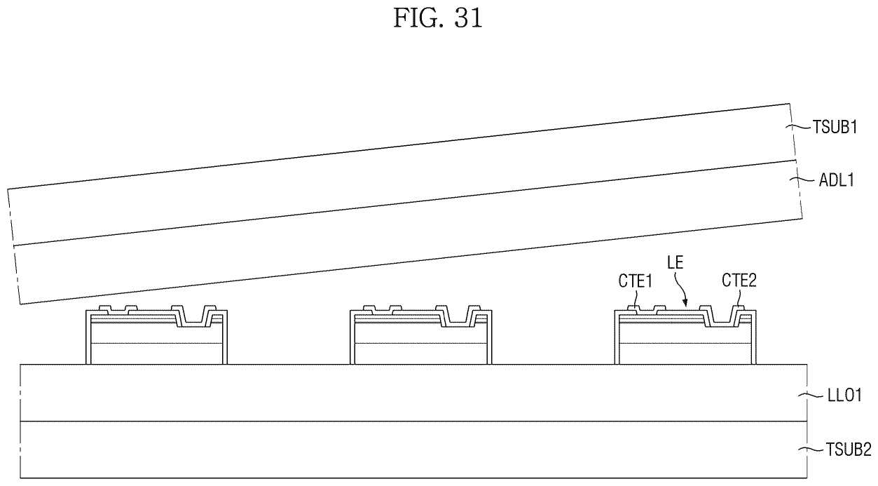

Third, as shown in FIG. 31, the plurality of light-emitting elements LE of the first transfer substrate TSUB1 may be moved to a first laser separation layer LLO1 located on a second transfer substrate TSUB2 (S113 in FIG. 28).

The second transfer substrate TSUB2 may be made of a transparent material to allow light to pass through. For example, the second transfer substrate TSUB2 may include a transparent polymer, such as polyimide, polyester, polyacrylic, polyepoxy, polyethylene, polystyrene, polyethylene terephthalate, or the like. The first laser separation layer LLO1 located on the second transfer substrate TSUB2 is a layer separable by laser irradiation, and may include, for example, a transparent polymer, such as polyimide.

When heat is applied while one surface of each of the plurality of light-emitting elements LE is in contact with the first laser separation layer LLO1, each of the plurality of light-emitting elements LE may be adhered or fixed to the first laser separation layer LLO1, and each of the plurality of light-emitting elements LE may be separated from the first adhesive layer ADL1 as the adhesive force of the first adhesive layer ADL1 weakens. One surface of each of the plurality of light-emitting elements LE may be opposite to the other surface on which the first contact electrode CTE1 and the second contact electrode CTE2 are located in each of the plurality of light-emitting elements LE.

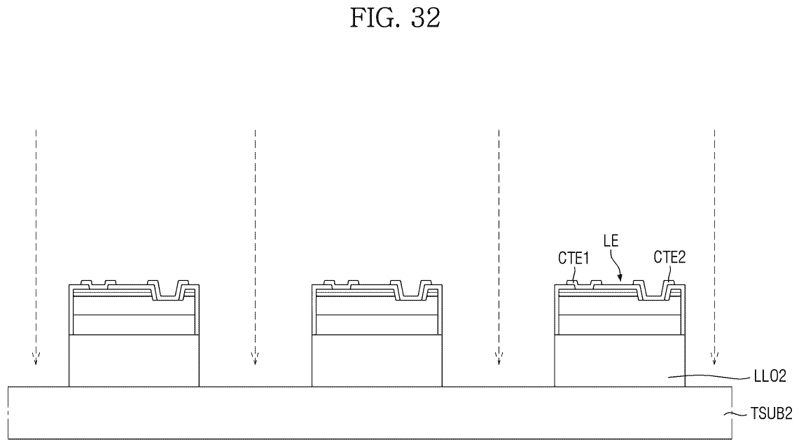

Fourth, as shown in FIG. 32, the first laser separation layer LLO1 may be etched using the plurality of light-emitting elements LE as a mask to form a second laser separation layer LLO2 located correspondingly to the plurality of light-emitting elements LE (S114 in FIG. 28).

The plurality of light-emitting elements LE might not be etched, but may be dry-etched using etching gas (DEG) in which only the first laser separation layer LLO1 is etched. That is, the first laser separation layer LLO1 may be etched using the plurality of light-emitting elements LE as a mask. As a result, the first laser separation layer LLO1 that does not overlap the plurality of light-emitting elements LE in the thickness direction of the second transfer substrate TSUB2 may be removed. Accordingly, the second laser separation layer LLO2 may be formed overlapping the plurality of light-emitting elements LE in the thickness direction of the second transfer substrate TSUB2. The second laser separation layer LLO2 may be located between each of the plurality of light-emitting elements LE and the second transfer substrate TSUB2 in the thickness direction of the second transfer substrate TSUB2.

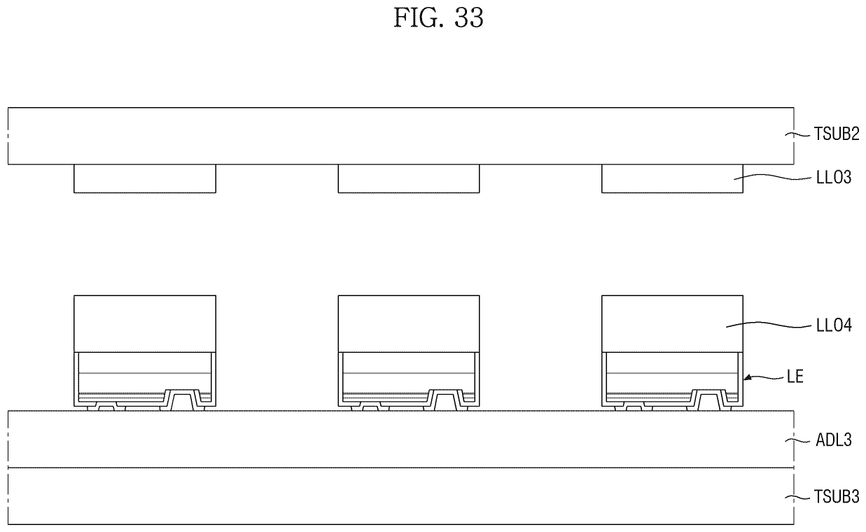

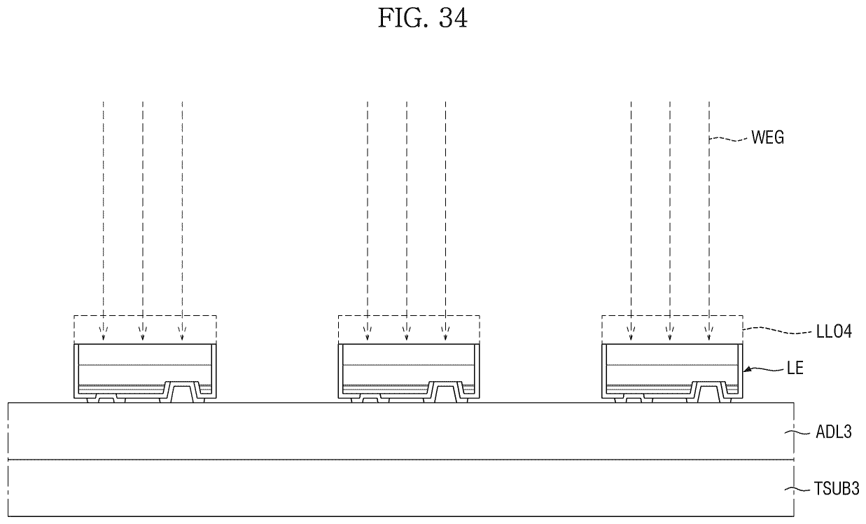

Fifth, as shown in FIGS. 33 and 34, the plurality of light-emitting elements LE may be transferred to a third adhesive layer ADL3 on a third transfer substrate TSUB3 by irradiating the second laser separation layer LLO2 with a laser and the second laser separation layer LLO2 is removed (S115 in FIG. 28).

The third transfer substrate TSUB3 may be made of a transparent material to allow light to pass through. For example, the third transfer substrate TSUB3 may include a transparent polymer, such as polyimide, polyester, polyacrylic, polyepoxy, polyethylene, polystyrene, polyethylene terephthalate, or the like. The third adhesive layer ADL3 located on one surface of the third transfer substrate TSUB3 may include an adhesive material for bonding the plurality of light-emitting elements LE. For example, the adhesive material may include urethane acrylate, epoxy acrylate, polyester acrylate, and the like.

If the first contact electrode CTE1 and the second contact electrode CTE2 of each of the plurality of light-emitting elements LE are contacted with the third adhesive layer ADL3 on the third transfer substrate TSUB3, and if a laser is irradiated onto the second laser separation layer LLO2, then the second laser separation layer LLO2 may be separated into a third laser separation layer LLO3 located on one surface of the second transfer substrate TSUB2 and a fourth laser separation layer LLO4 located on each of the plurality of light-emitting elements LE.

Then, the fourth laser separation layer LLO4 remaining on each of the plurality of light-emitting elements LE may be removed by a wet etching process. The plurality of light-emitting elements LEs are not etched, and the fourth laser separation layer LLO4 may be etched using an etching material WEG in which only the fourth laser separation layer LLO4 is etched.

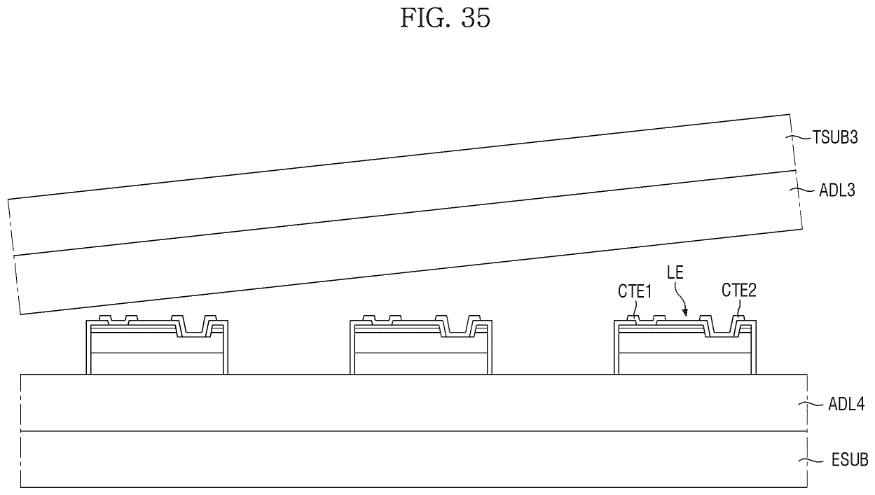

Sixth, as shown in FIG. 35, the plurality of light-emitting elements LE of the third transfer substrate TSUB3 may be moved to the fourth adhesive layer ADL4 on the light-emitting element substrate ESUB (S116 in FIG. 28).

Each of the light-emitting elements LE may be separated from the third adhesive layer ADL3 while contacting one surface of each of the plurality of light-emitting elements LE of the third transfer substrate TSUB3 to the fourth adhesive layer ADL4 on the light-emitting element substrate ESUB. In this case, the adhesive force of the fourth adhesive layer ADL4 may be higher than that of the third adhesive layer ADL3. One surface of each of the plurality of light-emitting elements LE may be opposite to the other surface of each of the plurality of light-emitting elements LE on which the first contact electrode CTE1 and the second contact electrode CTE2 are located.

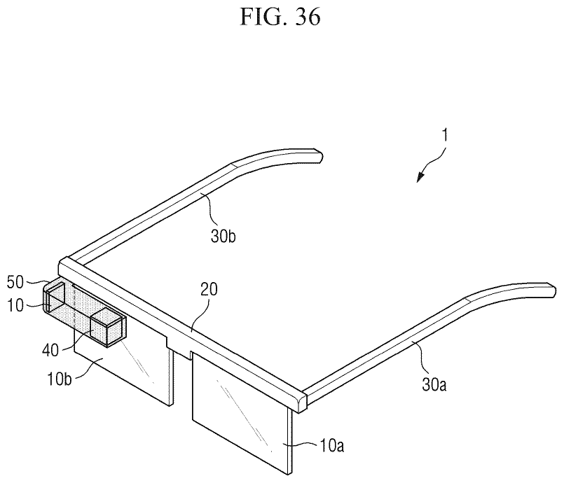

FIG. 36 is a diagram illustrating a virtual reality device including a display device according to one or more embodiments. FIG. 36 illustrates a virtual reality device 1 in which the display device 10 according to one or more embodiments is used.

Referring to FIG. 36, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 36 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 36, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 36 illustrates that the display device housing 50 is located at a right end of the support frame 20. However, one or more embodiments of the disclosure is not limited thereto. For example, the display device housing 50 may be located at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

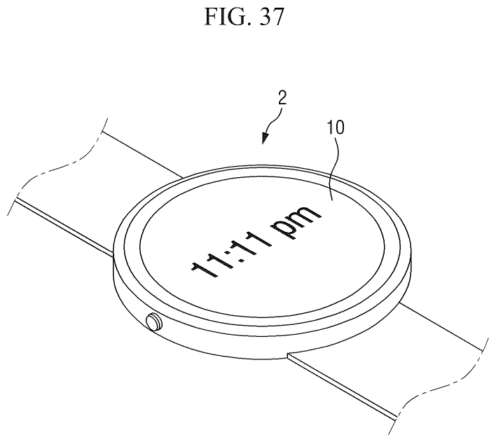

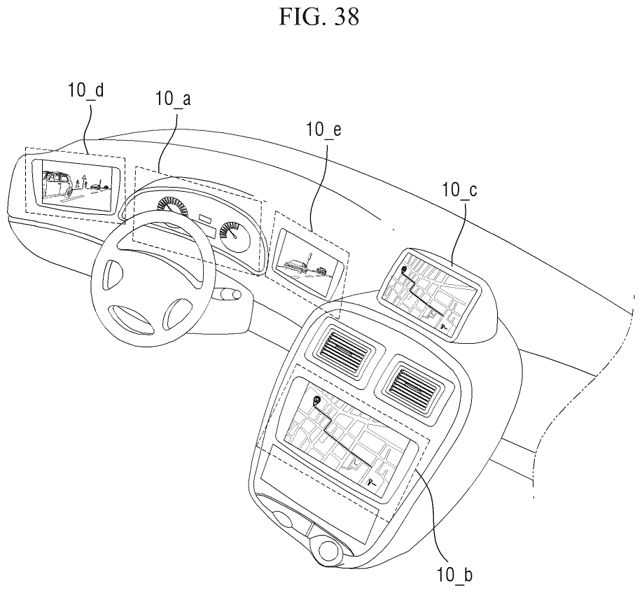

FIG. 37 is a diagram illustrating a smart device including a display device according to one or more embodiments.

Referring to FIG. 37, a display device 10 according to one or more embodiments may be applied to a smart watch 2 as one of smart devices.

FIG. 38 is a diagram illustrating a vehicle including a display device according to one or more embodiments. FIG. 38 illustrates a vehicle in which display devices according to one or more embodiments are used.

Referring to FIG. 38, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

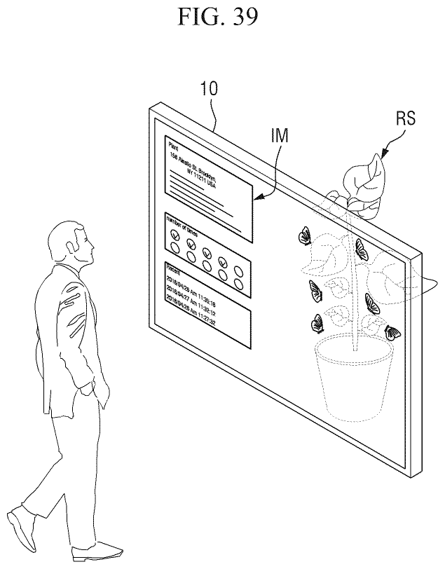

FIG. 39 is a diagram illustrating a transparent display device including a display device according to one or more embodiments.

Referring to FIG. 39, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the first substrate 110 of the display device 10 shown in FIG. 7 may include a light-transmitting portion that may transmit light therethrough or may be made of a material that may transmit light therethrough.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a substrate;
a first electrode and a second electrode above the substrate and spaced apart from each other;
an organic pattern layer between the first electrode and the second electrode;
a light-emitting element above the organic pattern layer;
a first contact electrode and a second contact electrode above a top surface of the light-emitting element;
a first reflective electrode on the first electrode, and extending along a side of the light-emitting element;
a second reflective electrode on the second electrode, and extending along a side of the light-emitting element;
a via layer covering a portion of the first reflective electrode and the second reflective electrode, and defining a first connection hole and a second connection hole;
a first connection electrode above the via layer, connecting the first reflective electrode and the first contact electrode through the first connection hole, and contacting the first reflective electrode on a side of the light-emitting element; and
a second connection electrode connecting the second reflective electrode to the second contact electrode through the second connection hole, and contacting the second reflective electrode on a side of the light-emitting element.

2. The display device of claim 1, wherein the first connection hole overlaps the first electrode, and exposes the first reflective electrode, and
wherein the second connection hole overlaps the second electrode, and exposes the second reflective electrode.

3. The display device of claim 2, wherein the first reflective electrode and the first connection electrode are connected in parallel with the via layer interposed therebetween, and
wherein the second reflective electrode and the second connection electrode are connected in parallel with the via layer interposed therebetween.

4. The display device of claim 2, wherein the light-emitting element comprises:
a third semiconductor layer above the organic pattern layer;
a second semiconductor layer above the third semiconductor layer;
an active layer above the second semiconductor layer;
a first semiconductor layer above the active layer; and
a protective film on a side surface of the third semiconductor layer, a side surface of the second semiconductor layer, a side surface of the active layer, and a side surface and a top surface of the first semiconductor layer, and defining a second opening and a third opening,
wherein the first contact electrode is in the second opening, and is connected to the first semiconductor layer, and
wherein the second contact electrode is in the third opening, and is connected to the second semiconductor layer.

5. The display device of claim 4, wherein the via layer is lower than the active layer.

6. The display device of claim 5, wherein the first reflective electrode and the second reflective electrode are higher than the active layer, and
wherein one end of the first reflective electrode and the second reflective electrode protrudes from the top surface of the via layer.

7. The display device of claim 6, wherein the first reflective electrode and the second reflective electrode have a higher reflectivity than the first connection electrode and the second connection electrode.

8. The display device of claim 7, wherein the first electrode, the second electrode, the first reflective electrode, and the second reflective electrode comprise an opaque metal material, and
wherein the first connection electrode and the second connection electrode comprise a transparent conductive oxide.

9. The display device of claim 2, wherein the first electrode and the second electrode are spaced apart from each other on a same plane, and protrude outwardly from the light-emitting element.

10. The display device of claim 9, wherein a width of the organic pattern layer is wider than a width of the light-emitting element.

11. The display device of claim 10, further comprising a reflective layer on a lower surface of the organic pattern layer between the first electrode and the second electrode, and
wherein the reflective layer has a higher reflectivity than the first connection electrode and the second connection electrode.

12. The display device of claim 2, further comprising:
a partition wall above the via layer, defining a light-emitting area, and filling connection holes defined by the via layer; and
a wavelength conversion layer in the space defined by the partition wall.

13. The display device of claim 12, further comprising a capping layer, an overcoat layer, and a color filter layer sequentially above the wavelength conversion layer and the partition wall.

14. A method of manufacturing a display device, the method comprising:
providing a light-emitting element above a light-emitting element substrate;
forming a first electrode and a second electrode spaced apart from each other above a substrate;
forming an organic pattern layer between the first electrode and the second electrode;
fixing the light-emitting element of the light-emitting element substrate to the organic pattern layer;
forming a first reflective electrode on a side of the light-emitting element on the first electrode;
forming a second reflective electrode extending on the side of the light-emitting element on the second electrode;
forming a via layer defining a first connection hole that overlaps the first electrode, and that exposes the first reflective electrode, and also defining a second connection hole that overlaps the second electrode, and that exposes the second reflective electrode;
forming a first connection electrode above the via layer and contacting the first reflective electrode on the side of the light-emitting element for connecting the first reflective electrode and a first contact electrode through the first connection hole;
forming a second connection electrode connecting the second reflective electrode to a second contact electrode through the second connection hole, and contacting the second reflective electrode on the side of the light-emitting element.

15. The method of claim 14, wherein forming the via layer comprises:
forming a via layer to cover a portion of the first reflective electrode and the second reflective electrode and to be lower than an active layer of the light-emitting element;
etching the first connection hole exposing the first reflective electrode at a position overlapping with the first electrode; and
etching the second connection hole exposing the second reflective electrode at a position overlapping with the second electrode.

16. The method of claim 15, wherein the first reflective electrode and the second reflective electrode are higher than the active layer in forming the second reflective electrode.

17. The method of claim 14, wherein the first reflective electrode and the second reflective electrode have a higher reflectivity than the first connection electrode and the second connection electrode.

18. The method of claim 14, wherein forming the first electrode and the second electrode spaced apart from each other on the substrate further comprises:
forming a recess on the light-emitting element substrate;
forming the first electrode and the second electrode with the recess therebetween; and
forming a reflective layer in the recess.

19. The method of claim 14, wherein fixing the light-emitting element to the organic pattern layer further comprises:
curing the organic pattern layer at a first temperature;
inserting a portion of the light-emitting element into the organic pattern layer; and
curing the organic pattern layer at a second temperature higher than the first temperature.

20. The method of claim 14, further comprising:
forming a partition wall above a via layer fixed to the organic pattern layer and defining a light-emitting area;
forming a first wavelength conversion layer in a region corresponding to a first sub-pixel, forming a second wavelength conversion layer in a region corresponding to a second sub-pixel, an forming a light transmission layer in a region corresponding to a third sub-pixel among the regions compartmentalized by the partition wall; and
forming a first color filter on the first wavelength conversion layer, forming a second color filter on the second wavelength conversion layer, and forming a third color filter on the light transmission layer.
